(19) United States
(12) Patent Application Publication
(10) Pub. No.: US 2025/0266190 A1
(43) Pub. Date: Aug. 21, 2025

(54) LOAD BANK APPARATUS

(71) Applicant: ULB, L.L.C., Wixom, MI (US)

(72) Inventors: Harish Raman bhai Patel, Northville, MI (US); Monali Harish Patel, Northville, MI (US)

(73) Assignee: ULB, L.L.C., Wixom, MI (US)

(21) Appl. No.: 19/056,118

(22) Filed: Feb. 18, 2025

Related U.S. Application Data
(60) Provisional application No. 63/556,149, filed on Feb. 21, 2024.

(51) Int. Cl. H01C 1/16; G01R 31/42; H01C 1/022; H01C 3/20

(52) U.S. Cl. CPC H01C 1/16; G01R 31/42; H01C 1/022; H01C 3/20

(57) ABSTRACT

An apparatus can a load bank module configured to electrically couple with at least one other load bank module. The load bank module and the at least one other load bank module can be further configured to electrically couple to a power source to dissipate power received from the power source. The load bank module can include trays including resistive components to dissipate the power received from the power source at a voltage level of the power source. A resistive component of the resistive components can include a coil, the coil can extending between a first end of the resistive component and a second end of the resistive component opposite the first end of the resistive component to form three or more turns of the coil.

### CROSS-REFERENCE TO RELATED PATENT APPLICATION

This application claims the benefit of, and priority to, U.S. Provisional Patent Application No. 63/556,149, filed Feb. 21, 2024, the entirety of which is incorporated by referenced herein.

### BACKGROUND

A load bank can be a system, device, piece of equipment, or apparatus that provides a resistive, inductive, or capacitive load to test a power source. For example, a building, such as a data center, a hospital, a factory, or an airport, can include a power source or backup power source. The power source can be a generator system, a battery system, an uninterruptible power supply, a photovoltaic system, a turbine system, or any other power generating or distribution system, apparatus, or piece of equipment. The load bank can be coupled with the power source to provide a test load that the power source can provide power to. The load bank can be used to load the power source in order to test, adjust, calibrate, or verify the performance of the power source. The load bank can be installed permanently or temporarily at the building, and can be used for periodic testing of the backup power source of the building. Load banks can further be used to test the power sources of aircraft, boats, vehicles or other stationary or moving platforms.

### SUMMARY

At least one aspect of the present disclosure is directed to an apparatus. The apparatus can include a load bank module configured to electrically couple with at least one other load bank module. The load bank module and the at least one other load bank module can be configured to electrically couple to a power source to dissipate power received from the power source. The load bank module can include trays including resistive components to dissipate the power received from the power source at a voltage level of the power source. The trays can removably couple with the load bank module. A resistive component of the resistive components including a coil, the coil extending between a first end of the resistive component and a second end of the resistive component opposite the first end of the resistive component to form three or more turns of the coil.

The apparatus can include load bank modules including the load bank module and the at least one other load bank module having a total bottom surface area. The total bottom surface area can include a length of 12.3 meters (or 14.63 meters (48 feet)) or less and a width 2.5 meters or less. The load bank modules can be configured to together dissipate at least 20 megawatts (e.g., up to 25 megawatts) of power received from the power source.

The voltage level can be up to 15,000 volts alternating current or 35,000 volts alternating current.

The load bank module can have dimensions. The dimensions can include a length of 2.5 meters or 3 meters or less. The dimensions can include a width of 2.5 meters or less. The dimensions can include a height of 2.9 meters or less. The load bank module can be configured to dissipate at least 4 megawatts of power received from the power source.

The apparatus can include the trays stacked in columns within an enclosure of the load bank module. The trays can electrically coupled together with bus bars. A first set of the trays can couple with a first phase of the power source. A second set of the trays can couple with a second phase of the power source. A third set of the trays coupled with a third phase of the power source.

The apparatus can further include a first fuse configured to disconnect a first set of the trays from a first phase of the power source responsive to a level of current of the first phase exceeding a first threshold. The apparatus can include a second fuse configured to disconnect a second set of trays from a second phase of the power source responsive to a level of current of the first phase exceeding a second threshold. The apparatus can include a third fuse to configured disconnect a third set of the trays from a third phase of the power source responsive to a level of current of the first phase exceeding a third threshold.

The load bank module can include lateral sides. At least one of the lateral sides includes a first rail. The trays can include at least one second rail to couple with the first rail for providing a simple way to allow the tray configured to install with the load bank module or to uninstall from the load bank module via the first rail and the second rail.

The trays can include at least one lateral wall including mica.

The trays can include a lateral wall that includes openings. The resistive components can be configured to be inserted from a first side of the lateral wall, through the openings, to a second side of the lateral wall.

The trays can include a lateral wall including a rows of openings from a bottom side of the lateral wall to a top side of the lateral wall, with a first row of the rows of openings offset from a second row of the rows of openings towards a third side of the lateral wall that extends from the top side to the bottom side. The resistive components can be configured to be inserted from a first side of the lateral wall, through the rows of openings, to a second side of the lateral wall.

The trays can include a lateral wall including openings. The resistive components may be installed within the tray, with bodies of the resistive components that are at least partially disposed on a first side of the lateral wall. At least a portion of the resistive components extend from the first side of the lateral wall, through the openings, to expose terminals of the resistive components on a second side of the lateral wall. The resistive components can include bus bars configured to couple the resistive components via the terminals on the second side of the lateral wall.

The apparatus can include a resistive component including the coil formed from a wire. The apparatus can include the wire extending back and forth from the first end of the resistive component to the second end of resistive component in a spiral pattern to form turns.

The resistive component can include a support member having a cylindrical shape, the support member extending from a first end of resistive component to a second end of the resistive component. The resistive component can include discs coupled with the support member and spaced between the first end of the resistive component and the second end of the resistive component. The discs include openings having circular shapes. The resistive component can include a wire extending back and forth from a first end of the resistive component to a second end of resistive through the openings in the discs in a spiral pattern to form turns.

The load bank module can include a fan apparatus disposed between a bottom of the load bank module and the trays of the load bank module. The fan apparatus can include at least one air guide vane (e.g., directional component) configured to direct an airflow from a first direction ninety degrees to a second direction. The fan apparatus can include blowers configured to pull air from outside the load bank module and the air guide vane to direct the airflow away from the bottom to pass through the trays and cool the resistive components.

The apparatus can include a tray including a first lateral side and a second lateral side opposite the first lateral side.

At least one aspect of the present disclosure is a method. The method can include providing a support member having a cylindrical shape. The method can include extending a coil between a first end of the support member to a second end of the support member opposite the first end form three or more turns of the coil. The method can include disposing the resistive component in a tray of multiple trays to dissipate power received from a power source. The method can include disposing the multiple trays in a load bank module.

The method can include stacking the trays in columns within an enclosure of the load bank module. The method can include coupling a first set of the trays with a first phase of the power source. The method can include coupling a second set of the trays with a second phase of the power source. The method can include coupling a third set of the trays with a third phase of the power source.

The method can include coupling a first rail with a lateral side of lateral sides of a tray of the trays. The method can include coupling a second rail with a lateral side of lateral sides of the load bank module. The method can include installing or uninstalling, via the first rail and the second rail, the tray with the load bank module.

The method can include disposing discs on the support member spaced from the first end to the second end. The method disposing a wire in the resistive component by passing the wire back and forth from the first end to the second end through openings in the discs in a spiral pattern to form turns.

At least one aspect of the present disclosure is directed to an apparatus. The apparatus can include a support member configured to install in, and remove from, a load bank, the support member including a first end and a second side opposite the first end. The apparatus can include a coil to extending between the first end of the support member and the second end of the support member to form turns of the coil.

The apparatus can include discs coupled with the support member and spaced between the first end of the support member and the second end of the support member, the discs including openings having circular shapes. The apparatus can include a wire extending back and forth from a first side of the support member to a second side of support member through the openings in the discs in a spiral pattern to form turns.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 is an example load bank.

FIG. 2 is an example load bank mounted on a trailer.

FIG. 3A is another example of a load bank mounted on a trailer.

FIG. 3B is an example of various numbers of load bank modules coupled together.

FIG. 3C is an example of two load bank apparatuses including load bank modules coupled together.

FIG. 3D is a front view of an example storage box of a load bank.

FIG. 3E is a perspective view of an example storage box of a load bank.

FIGS. 3F-3G are perspective views of an example transformer module of a load bank.

FIG. 3H is a back view of an example transformer module of a load bank.

FIG. 3I is a front view of an example transformer module of a load bank.

FIGS. 3J and 3K are cross-sectional views of an example transformer module of a load bank.

FIG. 4A is an example disassembled view of a load bank module including trays.

FIG. 4B is an example cross-sectional view of the load bank module of FIG. 4A including trays.

FIG. 5A is a front view of an example load bank module including trays.

FIG. 5B is an example bottom tray of a first load bank module of a load bank.

FIG. 5C is an example bottom tray of a subsequent load bank module coupled with the first load bank of FIG. 5B.

FIG. 6 is an disassembled view of a tray including resistive components.

FIG. 7 is an disassembled view of a tray including support members.

FIG. 8 is an example view of a tray including bus bars to form a circuit with resistive components.

FIG. 9 is a cross-section view of a tray including resistive components.

FIG. 10 is a side view of a tray including rails to install or uninstall from a load bank module.

FIG. 11 is an example view of a tray where a resistive component couples with a front lateral side of the tray.

FIG. 12 is an example view of a tray where a resistive component couples with a rear lateral side of the tray.

FIG. 13 is a rear view of a tray to install with a load bank module.

FIG. 14 is an example disassembled view of a resistive component including turns.

FIG. 15A is an example side view of a resistive component including turns.

FIG. 15B is an example wire spiral of a resistive component.

FIG. 15C is an example cross-sectional view of the resistive component along cross-section P-P of FIG. 15A.

FIG. 15D is an example cross-sectional view of a resistive component of a load bank along a length of the resistive component.

FIG. 16A is a disassembled view of an example fan apparatus.

FIG. 16B is a cross-sectional view of the example fan apparatus of FIG. 16A.

FIG. 16C is a front perspective view of an example air guide vane.

FIG. 16D is a back perspective view of an example air guide vane.

FIG. 16E is a front view of an example air guide vane.

FIG. 16F is a side view of an example air guide vane.

FIG. 16G is a cross-sectional view of an example air guide vane.

FIG. 17A is an example view of a high voltage side of load bank modules including fuses.

FIG. 17B is an example view of a low voltage side of load bank modules including columns of trays including resistive components.

FIG. 18 is an example circuit of load bank modules coupled with a power source.

FIG. 19 is another example circuit of load bank modules coupled with a power source

FIG. 20A is an example circuit of controllers of load bank modules that control the load bank modules.

FIG. 20B is an example user interface.

FIG. 21 is an example method of providing a load bank.

FIG. 22 is an example computing architecture of a controller.

### DETAILED DESCRIPTION

Following below are more detailed descriptions of various concepts related to, and implementations of, methods, apparatuses, and systems of a load bank apparatus. The various concepts introduced above and discussed in greater detail below may be implemented in any of numerous ways.

This disclosure is generally directed to a load bank apparatus. A load bank can be used to test, adjust, calibrate, or verify the performance of the power source. A load bank can be configured or rated to dissipate an amount of power from the power source, such as a maximum amount of power, an average amount of power, or a nominal amount of power. To test power source that generate a high amount of power (e.g., tens of megawatts (MW)), the load bank may be configured to dissipate the power in the form of heat via resistive components. While a load bank could be designed or manufactured to include a long length of wire for resistive heating components to dissipate a high amount of power, the load bank may be very large and heavy. Manufacturing, shipping, delivering, or storing a large load bank can be technically difficult and consume large amounts of resources. Furthermore, a load bank can be difficult to troubleshoot or repair. If individual components of the load bank malfunction or need servicing, it can be difficult for a technician to identify the component requiring servicing, access the component, and replace the component.

Furthermore, it can be difficult to have proper electrical insulation and isolation for a load bank with voltages up to 15,000 volts or 33,000 volts in a compact or small space. The high voltages and high amount of power dissipated can further cause high internal temperatures within a load bank, up to 400 degrees Celsius. This high amount of heat can cause structural challenges for resistive heaters and/or other structural components of the load bank.

To solve these, and other technical problems, technical solutions of this disclosure can include a load bank apparatus that can be modular and can operate at a high voltage. The load bank can be a system, apparatus, or piece or set of equipment. The modular load bank can include multiple load bank modules. Each load bank module can include a set of trays. Each tray can include a set of resistive component cartridges. The load bank modules, the trays, and the resistive components can efficiently utilize space to allow for high power dissipation (e.g., 10-20 megawatts (MW), 20 MW or more, less than 10 MW, greater than 7 MW) in a small foot print (e.g., a total bottom surface area with a length 12-13 meters and a width of 2-3 meters and a height of 2.9-3.1 meters). The modular load bank can be fit on a standard sized 40 foot or 48 foot trailer bed (12.2 meter or 14.63 meter trailer bed), which can have a length of 504 inches (12.8 meters) and a width of 102 inches (2.6 meters). In some implementations, load bank modules can be packaged or enclosed in a storage or shipping container. The storage or shipping container can range in size, for example, from 8 feet to 53 feet in length (e.g., 2.4-16.2 meters) with a width of 96 inches (e.g., 2.4-2.5 meters) and a height of 102 inches (e.g., 2.5-2.6 meters) or 120 inches (e.g., 3.0-3.1 meters).

The modular load bank can include resistive components that efficiently utilize space to dissipate a high amount of power in a low amount of space. This efficient use of space can allow the load bank to operate efficiently to dissipate power and heat, and directly operate on high voltage (e.g., 13,800-33,000 volts), without requiring a step down transformer or a larger enclosure for the load bank. Not requiring a step down transformer can save space and weight. A load bank might include a step down transformer to transform voltage from a source voltage (e.g., 13,800 volts) to a voltage for the load bank resistive components to operate on, e.g., 480 volts. However, the present load bank's resistive components can be coupled directly to the source voltage (e.g., three phases of 13,800 volts or up to 33,000 volts). Furthermore, the efficiency of the load bank can result in a weight of only 25 tons for 20,000 kW at a direct source voltage of 13,800 volts, which may be approximately 20% lighter than other 20,000 kW load banks. Because the enclosure size for the load bank can be kept small, the load bank can be fit on a smaller platform, such as the standard 40 foot trailer bed, and still dissipate a high amount of power, such as 20 MW or more. For example, the resistive components of the module load bank can be formed to include multiple turns of coiled or a spiral patterned wire. The resistive components can include turns or lengths of the coiled wire from a first end of the resistive component to a second end of the component, e.g., 4-13 turns. With the spiral pattern and 11-13 turns of wire, approximately 11 meters of wire can be fit into a cylindrical shaped cartridge approximately 1.3 meters long with a 1-3 inch (2.5-7.6 centimeters) diameter. The resistive components can be cartridge based components that can be installed or removed from a tray. This can allow for efficient access or servicing of the load bank apparatus.

The load bank modules can include trays in which resistive components are installed. The trays can include a housing shaped in a rectangular solid shape, cube shape, or any other shape. The resistive components can be removably coupled with the trays. For example, the resistive components can be inserted through openings in a lateral wall in the tray into a body, cavity, or interior of the tray. The resistive components can include terminals that extend past the openings in the housing. Bus bars can be coupled with the terminals to wire the resistive components together and electrically couple the resistive components to the power source to dissipate power. In this regard, the trays can form a circuit board or wiring board where resistive component cartridges can be installed and then wired together.

The trays can be stacked into multiple columns or rows to form a set or matrix of trays. The trays can be stacked within a load bank module. The load bank module can include a housing that stores, at least partially encloses, includes, or contains the trays and resistive component cartridges. The load bank modules can be wired or coupled together via bus bars, such as flexible bus bar. The load bank modules can be wired in parallel with each other and the power source. The load bank modules can be electrically coupled with the power source to load the power source and dissipate power.

The resistive components can be organized or disposed in trays, which can be organized or disposed in load bank modules such that heat is efficiently dissipated. The load bank apparatus can include blowers that pull air in from outside the load bank, pass the air upwards through the load bank, and carry heat out of openings in the top of the load bank. In this regard, even if high internal temperatures are reached, such as 400 degrees Celsius, the load bank can still have structural integrity when undergoing high mechanical stress.

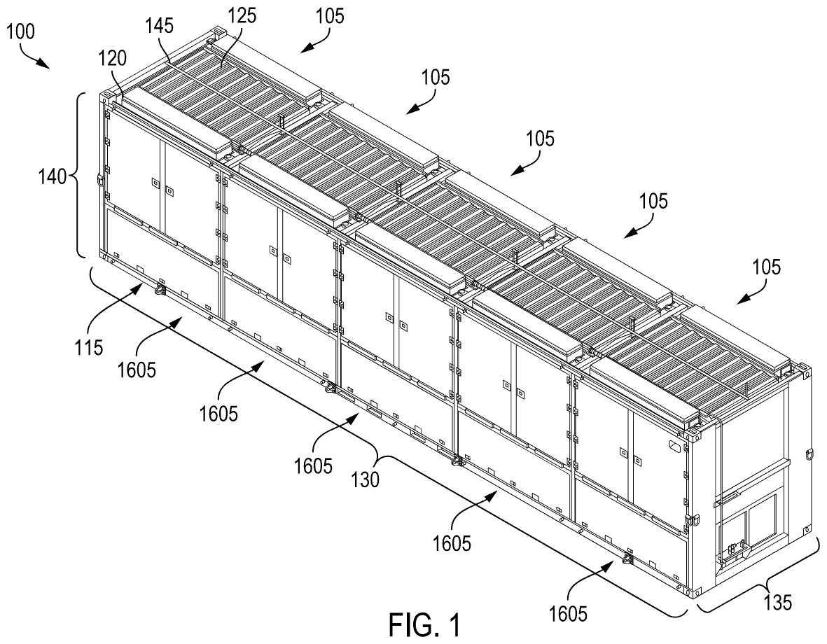

Referring now to FIG. 1, among others, an example load bank 100 is shown. The load bank 100 can be an apparatus, a system, or a group or set of components or pieces of equipment. The load bank 100 can be electrically coupled with a power source, such as the power source of a building, vehicle, or other stationary or mobile platform. The load bank 100 can provide a load for the power source. The power source can be a generator system, a battery system, an uninterruptible power supply, a photovoltaic system, a turbine system, or any other power generating system, apparatus, or piece of equipment. The load bank 100 can include at least one load bank module 105. The load bank module 105 can be an apparatus, a system, cabinet, a piece of equipment, or a device. The load bank 100 can include one to six load bank modules 105. According to another exemplary embodiment, the load bank 100 can include at least two load bank modules 105. According to another exemplary embodiment, the load bank 100 can include five load bank modules 105. According to still other exemplary embodiments, the load bank 100 can include at least five load bank modules 105. The load bank 100 can have a maximum rated load bank capacity of 4, 8, 16, 20, or 24 MW. The physical size of the containers or enclosures of the load bank 100 can depend on the maximum rating of the load bank 100. For example, a 20 MW rated capacity for a load bank 100 can include a container of at least 40 feet in length. For a load bank capacity over 20 or 24 MW, the load bank 100 can include a container of 50 or 53 feet in length.

The load bank 100 can have a resolution, for example, a standard 1,333 kW resolution. In some implementations, the load bank 100 can have a resolution of 20 kW, 40 kW, 80 kW, 160 kW, 320 kW, 640 kW, or any other resolution. The physical size and dimensions of the containers or enclosures of the load bank module 105 can be adapted to provide higher or lower resolution, depending on the resolution selected for the load bank 100.

The load bank modules 105 can be electrically coupled together. For example, a load bank module 105 can be electrically coupled with at least one other load bank module 105, or all or a subset of the other load bank modules 105 of the load bank 100. The load bank modules 105 can be directly or indirectly electrically coupled with the power source to receive power from the power source and dissipate the power. The load bank modules 105, via resistive components, can dissipate the power by converting the power to heat. Each load bank module 105 can dissipate an amount of power, 3.5 MW to 4.5 MW, 3 MW to 5 MW, less than 3 MW, more than 5 MW, or 1 MW to 5.6 MW. Each load bank module 105 can dissipate substantially 4 MW. Each load bank module 105 can dissipate at least 4 MW. The load bank module 105 can have a length of 2.5 meters or 3 meters or less. For example, the load bank module 105 can have a length of 2.3-2.7 meters. The length of the load bank module 105 can be 2-3 meters. The length of the load bank module 105 can be less than 2 meters. The length of the load bank module 105 can be greater than 3 meters. The load bank module 105 can have a width of 2.5 meters or less (e.g., 96-102 inches or less). For example, the load bank module 105 can have a width of 2.4-2.6 meters. The width of the load bank module 105 can be 2.3-2.7 meters. The width of the load bank module 105 can be less than 2.3 meters. The width of the load bank module 105 can be greater than 2.7 meters. The load bank module 105 can have a height of 2.9 meters or less (e.g., 114 inches or less). For example, the load bank module 105 can have a height of 2.8-3.0 meters. The height of the load bank module 105 can be 2.7-3.1 meters. The height of the load bank module 105 can be less than 2.7 meters. The height of the load bank module 105 can be greater than 3.1 meters. The load bank modules 105 can be wired or coupled together to dissipate a total amount of power. For example, the load bank 100 can dissipate 18-22 MW, 17-23 MW, less than 17 MW, or more than 23 MW. The load bank 100 can dissipate approximately 20 MW. The load bank 100 can dissipate at least 20 MW of power. The load bank 100 can have a capacity to dissipate up to 50 MW of power.

The load bank module 105 can include a housing 115. The housing can include lateral sides, e.g., a first lateral side, a second lateral side, a third lateral side, a fourth lateral side, a top side, a bottom side. The housing 115 can form a rectangular solid, a cube, a prismatic shape, or any other shape. The housing 115 can be formed from aluminum or steel. A top side of 120 of the load bank can include an opening 125. The opening 125 can allow air heated by resistive components disposed within the load bank module 105 to exit the housing of the load bank module 105. The load bank modules 105 can include louvers 145. The louvers 145 can be coupled with edges or surfaces of the top side 120. The louvers 145 can open or close. The louvers 145 can be operated by a manual lever. The louvers 145 can move between a first position, a second position, and a third position. The louvers 145 can move to a closed position to limit an airflow through the opening 125. The louvers 145 can move to open positions to allow or increase an airflow through the opening 125. The louvers 145 can move to a defrost position where the louvers 145 are partially opened (e.g., approximately 5 degrees open). The louvers 145 can rotate, turn, or move on hinges or hinging apparatuses.

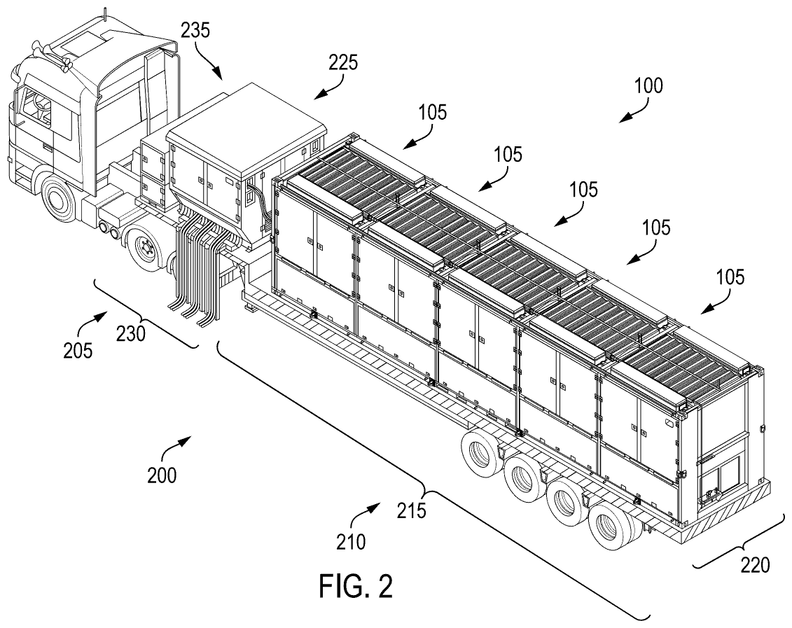

The load bank module 105 can include computer systems, displays, or user interfaces for interacting with or controlling the load bank modules 105. The power source can be electrically coupled with the load bank 100 via a transformer module 125 (shown in FIG. 2). The load bank 100 can have a total footprint or total bottom surface area. The total bottom surface area can have a length 130 and a width 135. The load bank 100 can have a length 130. The length 130 can be 12.1-12.4 meters long. The length 130 can be 12-12.5 meters long. The length 130 can be less than 12 meters long. The length 130 can be greater than 12.5 meters long. The length 130 can be 12.3 meters or less. The length 130 can be 14.63 meters (48 feet) or less. The length can be approximately 480 inches (12192 millimeters). The width 135 can be 2.4-2.6 meters. The width 135 can be 2.3-2.7 meters. The width 135 can be less than 2.3 meters. The width 135 can be greater than 2.7 meters. The width can be 2.5 meters or less. The width can be approximately 102 inches (2591 millimeters). The load bank 100 can have a height 140. The height 140 can be 2.8-3.0 meters. The height 140 can be 2.7-3.1 meters. The height 140 can be less than 2.7 meters. The height 140 can be greater than 3.1 meters. The height 140 can be approximately 114 inches (2896 millimeters). Each load bank module 105 can dissipate a high amount of power, e.g., 4,000 kW in a small area, e.g., an 8 foot wide and 9 foot high volume for a high voltage, e.g., 13,800 volts AC. Overall, the load bank 100 can dissipate 20,000 kilowatts at 13,800 volts in a 40 foot wide and 8 foot high volume.

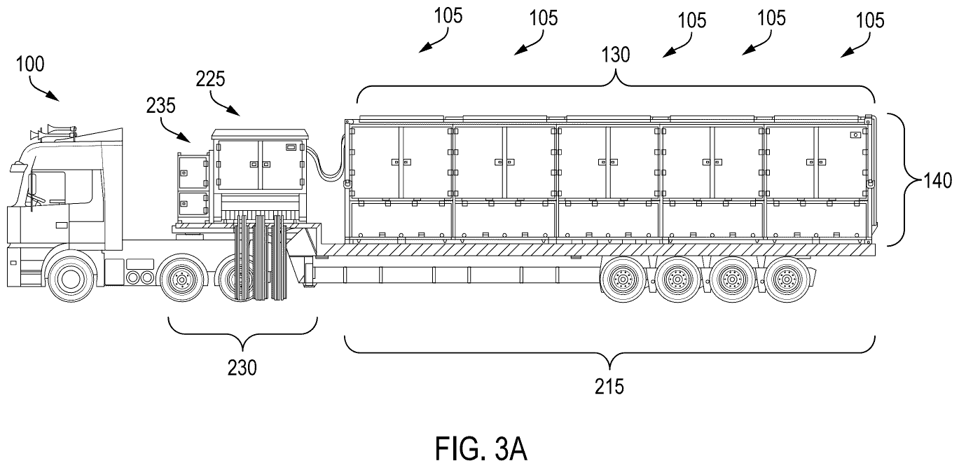

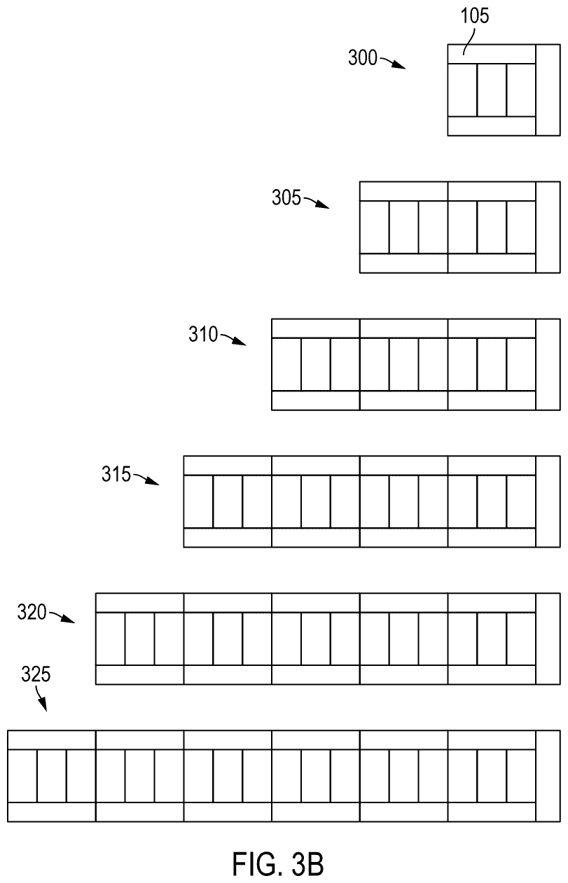

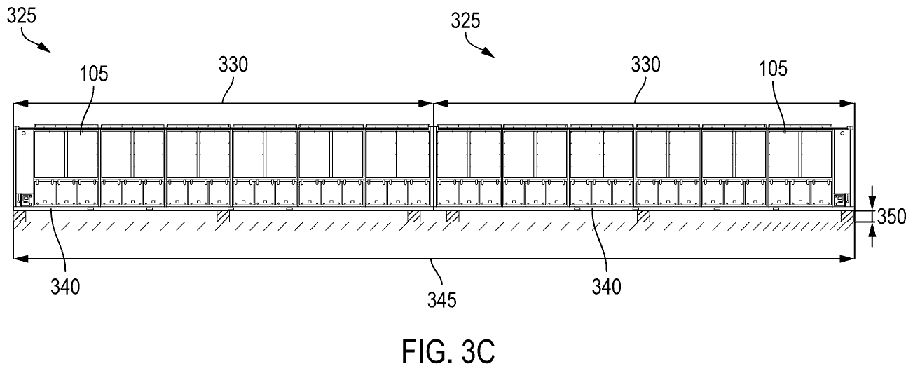

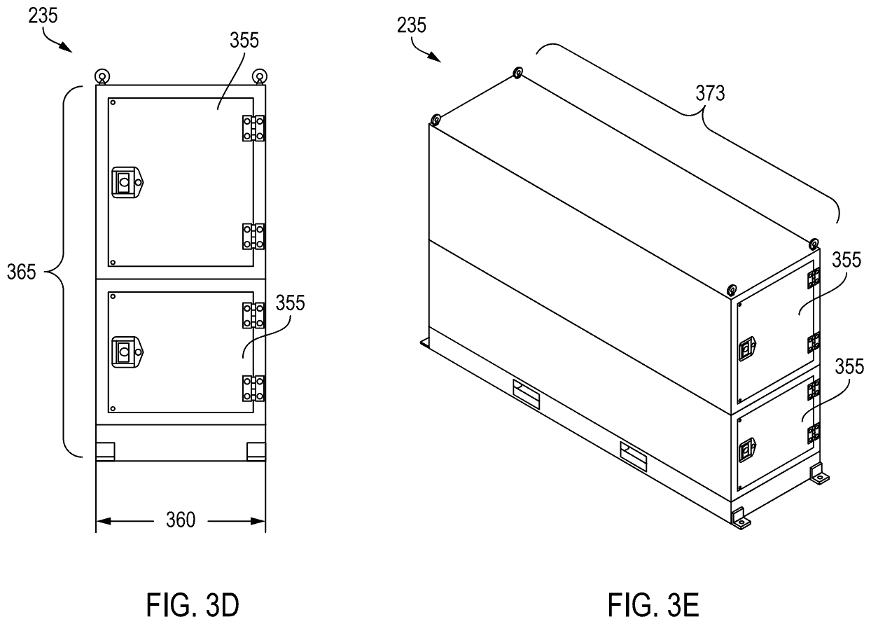

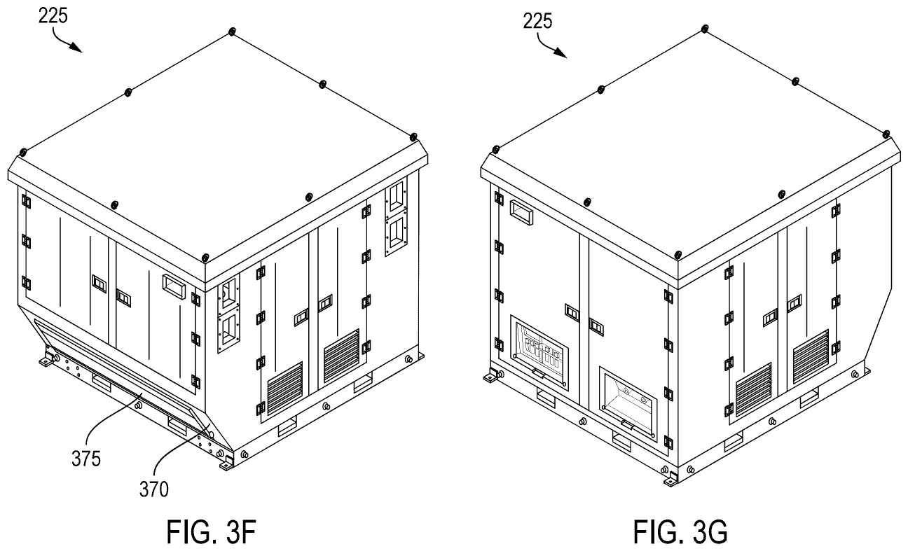

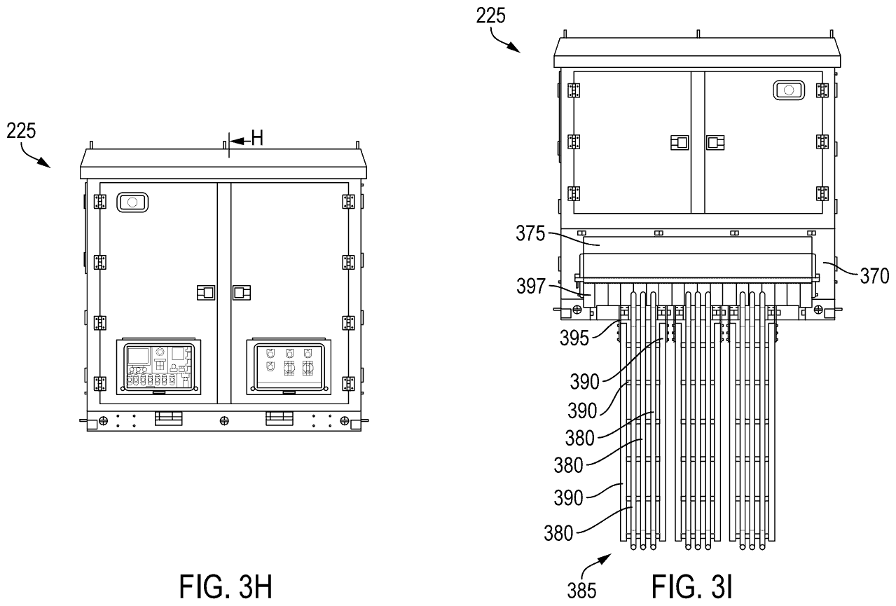

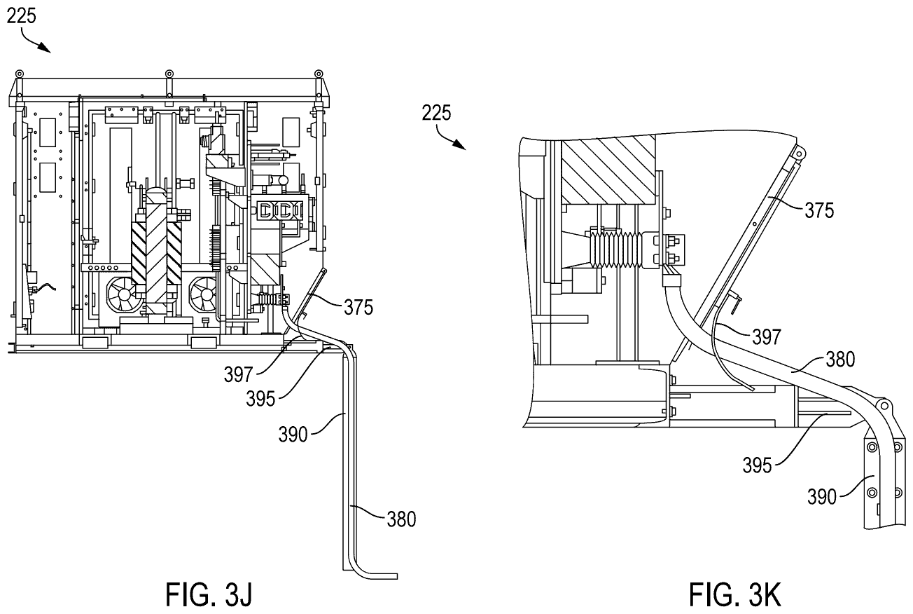

Referring now to FIGS. 2-3A, among others, the load bank 100 is illustrated mounted on a trailer 200. The trailer 200 can be any type of trailer, such as a two or three axel trailer or a drop deck trailer. The trailer 200 can be or include a flat surface that the load bank 100 can rest on and be supported by. The trailer 200 can include any platform, deck, apparatus, or vehicle that includes a platform to carry the load bank 100. The load bank 100 can be sized to fit on or within outer boundaries of the trailer 200. The load bank modules 105 can be disposed on a rear portion 210 of the trailer 200. The rear portion 210 can be a trailer deck, a main trailer deck, or a rear trailer deck. The rear portion can have a length 215 and a width 220. The length 215 can be 12.7-12.8 meters. The length 215 can be 12.6-12.9 meters. The length 215 can be less than 12.6 meters. The length 215 can be greater than 12.9 meters. The length 215 can be approximately 42 feet (43,282 millimeters). The rear portion 210 can have a width 220. The width 220 can be 2.4-2.6 meters. The width 220 can be 2.3-2.7 meters. The width 220 can be less than 2.3 meters. The width 220 can be greater than 2.7 meters. The load bank 100 can be transportable by the trailer 200 as one assembly or package (instead of in multiple separate assemblies or packages), e.g., can meet DOT USA transportation requirements such as height restrictions.

The trailer 200 can include an upper deck 205. The upper deck 205 can be coupled, attached, or connected to the lower deck 210. Containers or assemblies for the load bank 100 can be installed on the lower deck 210, while a transformer package can be installed on the upper deck 205. A transformer system, apparatus, or module 225 can fit or be disposed with an area, space, or section of the upper deck 205. The transformer module 225 can provide a low voltage for internal power control. The power provided to the load bank modules 105 can be high voltage (e.g., 13,800-15,000 volts or up to 33,000 volts), and may not be stepped down by the transformer module 225, or any other transformer. Because the load bank modules 105 can include trays including mica walls, resistive cartridges with long distances of coils of thin long wire formed into turns, and/or efficient cooling airflow, the load bank modules 105 can be rated for high voltages, and can couple directly with the high voltage of power sources, without requiring any step down transformer. The transformer module 225 can have a bottom surface area that fits on or within an outer boundary of the upper deck 205. The upper deck 205 can have a length 230. The length 230 can be 2.5-2.6 meters long. The length 230 can be 2.4-2.7 meters long. The length 230 can be less than 2.4 meters. The length 230 can be greater than 2.7 meters long. The length 230 can be approximately 2591 millimeters long (102 inches). The upper deck 205 can have a width of 220. Furthermore, a storage box 235 can be disposed on the upper deck 205 along with the transformer module 225. In some embodiments, the load bank modules 105 can provide 15 MW, 8 MW, or 5 MW at 33,000 volts, which can be used for a 40 foot, 30 foot, or 20 foot container. In some embodiments, the load bank 100 can be a 48 foot (14.63 meter) 24 MW load bank with a transformer module 225. In some embodiments, the load bank 100 can be a 48 foot (14.63 meter) 20 MW load bank without a transformer module 225.

In some implementations, the load bank 100 can be installed on a surface other than the decks 205 and 210 of the trailer 200. For example, the load bank 100 can be installed on the ground. For example, the load bank 100 can be installed on a concrete surface, a reinforced concrete surface, an asphalt surface, or a gravel surface. The load bank 100 can be installed in a parking lot, in a specialized load bank area, or in any other location next to or near a building or campus.

Referring now to FIG. 3B, among others, examples of various numbers of load bank modules coupled together are shown. FIG. 3B depicts load banks 300-325. The load banks 300-325 can include different numbers of load bank modules 105. The load bank modules 105 can be coupled together via one set of bus bars. The load bank modules 105 can be coupled with a continuous or common bus bar that runs a length of the load bank. The load bank modules 105 can be coupled on the same electrical bus. Jumpers can couple multiple load banks with the continuous bus bar.

The load bank modules 105 can be daisy chained together. For example, load bank 300 can include a single load bank module 105 and a transformer module 225. The load bank 305 can include two load bank modules 105. The load bank 310 can include three load bank modules 105. The load bank 315 can include four load bank modules 105. The load bank 320 can include five load bank modules 105. The load bank 325 can include six load bank modules 105. In some implementations, a load bank can include more than six load bank modules 105.

Referring now to FIG. 3C, among others, an example of two load bank apparatuses 325 including load bank modules 105 coupled together is shown. The load bank 100 can be modular, and can be formed from load bank modules 105 rated up to 4 MW. For example, load bank modules 105 can be packaged as one assembly in a group of load bank modules 105 (e.g., 1, 2, 3, 4, 5, 6, 7, 8, 9, 10, 11, or 12 load bank modules 105 for power ratings of up to 4, 8, 12, 16, 20, 24, or up to 48 MW) in a container of a length up to 53 feet, or two containers of 53 feet. The load bank 100 can include 1 to 6 load bank modules 105, in some embodiments. To prove a capacity over 20 MW or 24 MW, two load bank containers can be installed on a common base, with a common electrical power bus (e.g., 14 kV bus) for incoming power for the load banks. The containers can be 40 or 50 feet long, or as long as needed.

Each load bank apparatus 325 can be mounted on an independent platform 340, or on one single platform 340. Each load bank module 105 can be rated to dissipate 1-5.6 MW. The load bank container assembly can be installed in various configurations, such as on a 40 foot flatbed trailer truck, or in a 40 foot container on the ground with riser blocks. In some implementations, multiple load bank modules 105 can be packed on a single common base or frame 340 as one assembly 325. In this regard, the multiple load bank modules 105 can provide up to 33.6 MW. Similarly, if two assemblies 325 are daisy chained together, the two assemblies could provide a total of 67.2 MW. The load bank apparatuses 325 can be elevated above a floor or surface. For example, the platforms 340 can be raised a distance 350 a minimum of 10 inches from the floor, and a maximum of 15 inches from the floor via one or more supports or riser blocks. In some implementations, the riser blocks or other suitable structure can raise the load bank 100 off the ground. For example, the riser blocks can provide elevation of 24 to 40 inches. The elevation provided by the riser blocks can prevent the load bank modules 105 from being exposed to ground water that rises to a high level. In some implementations, the ground that the load bank modules 105 are installed above can be of a suitable material, such as concrete, to support up to 45,000 pounds of weight, while maintaining the load bank modules 105 in a level position. For example, the surface that the load bank modules 105 are installed on can be 8 inches thick reinforced cement concrete (RCC).

The load bank apparatuses 325 can be disposed in a row, and coupled together on at least one continuous bus bar. Each load bank apparatus 325 can include a number of load bank modules 105. Each load bank apparatus 325 can have a length 330. The length 330 can be 50 feet, and therefore the total length 345 of the load bank apparatuses 325 can be 100 feet. The length 330 can be 15.2-15.3 meters. The length can be 15.1-15.4 meters. The length can be less than 15.1 meters. The length can be more than 15.4 meters.

Referring now to FIGS. 3D-3E, the storage box 235 is shown in greater detail. The storage box 235 can include one or multiple compartments covered by doors 355. For example, the storage box 235 can include a stacked column of two or more compartments covered by doors 355. The compartments of the storage box 235 can store equipment, tools, space parts, or any other component or device for the load bank 100. The storage box 235 can be sized to fit along with the transformer module 225 on the upper deck 205. The storage box can have a width 360. The width 360 can be approximately 711 millimeters. The width 360 can be 700-720 millimeters. The width 360 can be 680-740 millimeters. The width 360 can be less than 680 millimeters. The width 360 can be greater than 740 millimeters. The storage box 235 can include a height 365 of approximately 1572 millimeters. The height 365 can be 1560-1580 millimeters. The height 365 can be 1550-1590 millimeters. The height 365 can be less than 1550 millimeters. The height 365 can be greater than 1590 millimeters. The length 373 can be approximately 2438 millimeters. The length 373 can be 2430-2450 millimeters. The length 373 can be 2420-2460 millimeters. The length 373 can be less than 2420 millimeters. The length 373 can be greater than 2460 millimeters.

Referring now to FIGS. 3F-3K, the transformer module 225 is shown, according to an exemplary embodiment. The transformer module 225 can have a box or prismatic shaped enclosure. The enclosure of the transformer module 225 can have a sloped surface 370 including a door 375. The sloped surface 370 can include at least one opening covered by the door 375, and at least one opening for cables 380. The cables 380 can be various phases of an AC power source (e.g., a building, a campus, a vehicle, a plane, etc.). The cables 380 can be guided to the enclosure of the transformer module 225 via at least one cable guide 385. The cable guide 385 can be a ladder or cage. The cable guide 385 can include members 390. For example, the cable guide 385 can include two parallel members that are hung from brackets 395 coupled with the enclosure of the transformer module 225. Each parallel member 390 can be coupled to the enclosure of the transformer module 225 via a bracket 395. The parallel members 390 can be coupled with the brackets 395 via a hinge, and can rotate about the bracket 395. The cable guide 385 can include members 390 extending between the parallel members 390.

The transformer module 225 can include at least one curtain 397. The curtain 397 can be formed from rubber, plastic, or any non-conductive material. The curtain 397 can be hung or disposed from a bottom edge of the door 375, and can cover or partially cover the cables 380 where the cables enter into the enclosure of the transformer module 225. The curtain 397 can be segmented into portions or flaps such that some flaps can be flush with a bottom of the side 370, and other flaps can be raised to allow a cable 380 to enter into the enclosure of the transformer module 225. FIGS. 3J-3K depict a cross-sectional view of the transformer module 225 taken along the cross-section H-H of FIG. 3H, illustrating the cables 380 guided into the enclosure of the transformer module 225 by the cable guide 390.

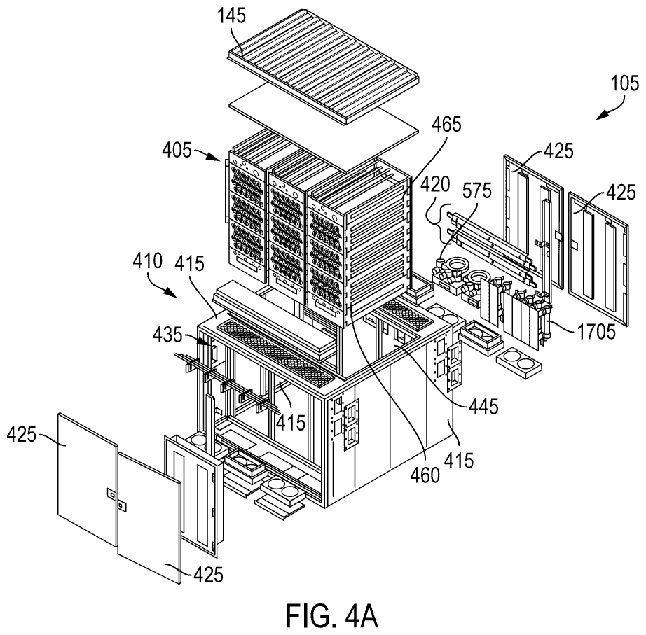

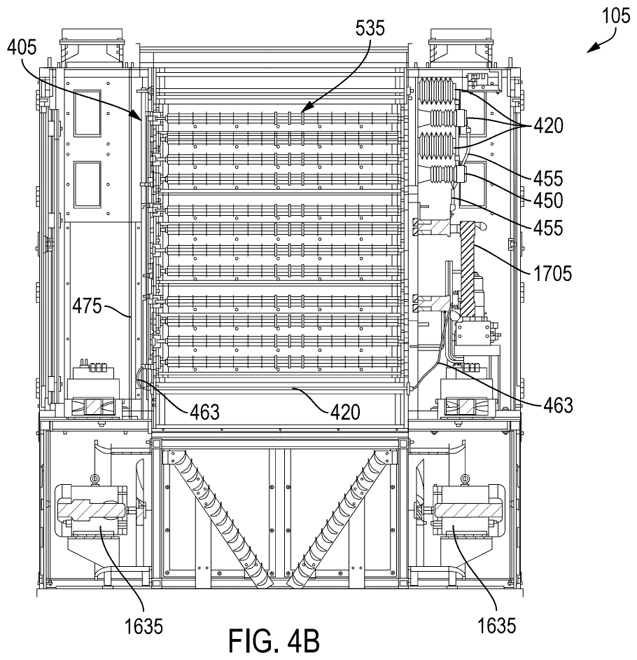

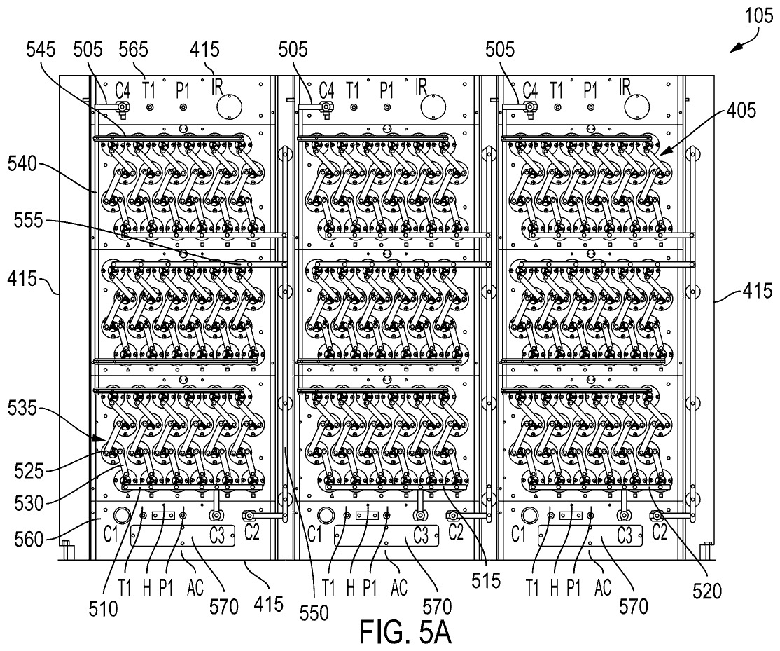

Referring now to FIGS. 4A-B, among others, an example disassembled view of load bank module 105 including heater trays 405 is shown. The load bank module 105 can include at least one system, device, apparatus, cabinet, heater tray, or tray 405. The load bank module 105 can include multiple trays 405 disposed, contained, included, or positioned within a housing 410 of the load bank module 105. The housing 410 can have a prismatic shape, a rectangular shape, or a cube shape. The housing 410 can form an open space, an area, or a cavity. The housing 410 can be made from or include steel, aluminum, tungsten, or any other material. The housing 410 can include lateral sides 415 that form the inner space of the load bank module 105. The lateral sides 415 can be top sides, bottom sides, or lateral sides. The lateral sides 415 can form inner sides, e.g., within a cavity or space of the load bank module 105. The trays 405 can sustain operating temperatures at the four vertical walls of the trays 405 up to 500-600 degrees Celsius. The four vertical walls of the trays 405 can be rated up to 15,000 volts or 33,000 volts. The trays 405 can provide continuous guided support for a resistor cartridge to be removed, e.g., pulled out, and re-inserted, e.g., pushed in. In some implementations, the trays 405 can be completely removed or uninstalled, while the resistor cartridges are fully supported and remain fixed to the trays 405. Similarly, a tray 405 of resistor cartridges can be installed in the load bank module 105, a first tray 405 can be removed and another tray 405 can be inserted into the load bank module 105 to replace the first tray.

The trays 405 can be organized in columns, one stacked over another. The trays 405 can be physically stacked on one another, or can be stacked over each other with spaces in between the trays 405. The trays 405 can be stacked in one, two, three, or more columns. The trays 405 can be organized in a matrix, with columns and rows of trays 405. The trays 405 can be stacked in columns for individual phases. For example, a first column of trays 405 can be coupled with a first phase of a power source, a second column of trays 405 can be coupled with a second phase of the power source, and a third column of trays 405 can be coupled with a third phase of the power source. The trays 405 can include resistive components or cartridges. Each cartridge can dissipate energy in the form of heat to provide a load for a particular tray 405 that the load bank 100 provides for a power source.

The load bank module 105 can be electrically coupled with at least one other load bank module 105 and/or the power source via bus bars 420. The bus bars 420 can be electrically coupled with the resistive components 535 of the trays 405. The bus bars 420 can be electrically coupled with another load bank module 105. The bus bars 420 can be electrically coupled with a power source. A first load bank module 105 can be electrically coupled with a power source through or via an electrical coupling with a second load bank module 105 via the bus bars 420. The load bank module 105 can include multiple bus bars 420 for multiple different phases of an alternative current (AC) power source. For example, the load bank module 105 can include a first bus bar 420 to couple with a first phase of the power source, a second bus bar 420 to couple with a second phase of the power source, and a third bus bar 420 to couple with a third phase of the power source. The bus bars 420 can include a neutral bus bar 450 and at least one flexible bus bar 455. Furthermore, the load bank module 105 can include at least one cable 463 to fuses 1705, e.g., at least one wire for each phase A, B, and C and neutral. The load bank module 105 can include a cover 475 over all bus bars, jumpers, connections, etc.

The load bank module 105 can include at least one door 425. The door 425 can open outwards away from the inner space of the load bank module 105 to expose an opening 435 into the load bank module 105. The opening 435 can be formed from ends of lateral, top, and bottom sides 415. The doors 425 can be coupled to opposite lateral sides 415 via a hinging component to rotate the doors 425 between closed and open positions.

The load bank module 105 can include a rear opening opposite the opening 435. The rear opening can be covered by doors 425. The doors 425 covering the rear opening can open opposite the doors 425 covering the opening 435. The load bank module 105 can include sheets 445. The sheets 445 can be disposed across the rear opening between the lateral sides 415 and the doors 425. The sheets 445 can be made of polycarbonate and can be clear or transparent. The load bank module 105 can include panels. The panels can be electrical panels that cover or secure electrical components or systems of the loads bank module 105. The load bank module 105 can include sheets that can be made or formed from mica, and be disposed on an inner side of the sheet 445.

The trays 405 can include connectors 460. The connectors 460 can be disposed on an outer side 465 of the trays 405. The connectors 460 can extend from a first end or front of the tray 405 to a second end or rear of the tray 405. The connectors 460 can be rails, snaps, slides, or other components that couple the trays 405 to the lateral sides 415. The lateral sides 415 of the housing 410 can include connectors. The connectors 460 of the trays 405 can couple with connections of the lateral sides 415. The connectors 460 and connectors of the lateral sides 415 can couple, e.g., one rail coupling onto or over another rail. The connector 460 can move on or slide on the connector. The inner surfaces of the lateral sides 415 of the housing 410 can include connectors. The outer surfaces of the lateral sides 415 disposed within the housing 410 can include connectors.

The trays 405 can removably couple with the load bank modules 105. The trays 405 can couple or de-couple from the load bank 105. The trays 405 can install from an outer side of the housing 410 into the housing 410. The connectors 460 can be connected with the connectors of the lateral side 415 and installed into the housing 410. The trays 405 can install with the housing 410. The trays 405 can be connected, from an outer side of the housing 410, to the connectors of the lateral sides 415 and pushed into or through the opening 435 into the housing 410. The trays 405 can be pulled out of the load bank module 105 on the connectors 460. For example, rails 460 can be mounted onto rails coupled to the lateral sides 415 of the housing 410, and the trays 405 can slide into or out of the housing 410. The trays 405 can be installed into the housing 410 by passing the trays 405 from an outer side of the housing 410, through the opening 435, and into the housing 410. The trays 405 can be uninstalled from the housing 410, from an inner side of the housing 410, through the opening 435, and out of the housing 410.

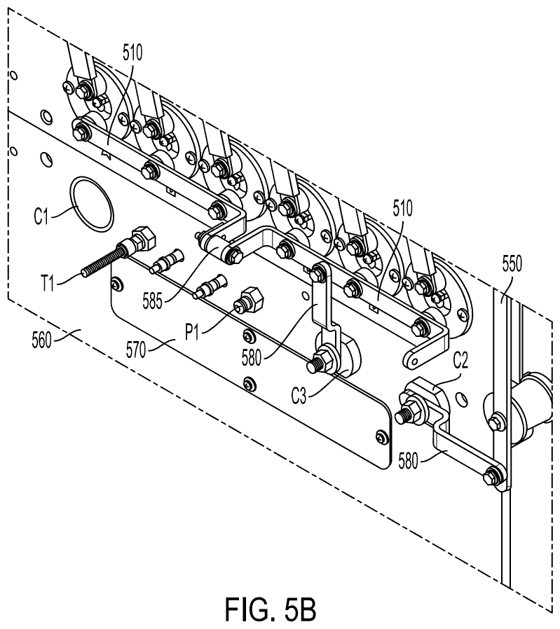

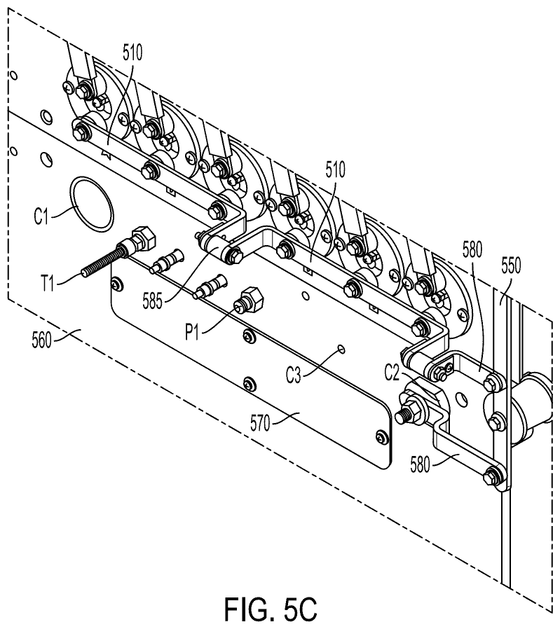

Referring now to FIG. 5A, among others, an example load bank module 105 including trays 405 is shown. The load bank module 105 can be wired via bus bars. For example, the load bank module 105 can include ground or neutral bus bars 505. The neutral bus bars 505 can provide a current return path to the power source. The bus bars 505 can run horizontally along a top of the load bank module 105. The bus bar 505 can extend perpendicular to the first lateral side 415 or the second lateral side 415. The bus bar 505 can extend parallel to a top side 415 of the housing 410.

Vertical bus bars 540 can extend from the horizontal bus bars 505 downwards towards a bottom side 415 of the housing 410. The horizontal bus bar 505 and the vertical bus bars 540 can be coupled together via a bolt or screw and be in an electrical connection. The horizontal bus bars 505 and the vertical bus bars 540 can be integrally formed. The vertical bus bars 540 can extend downwards away from the horizontal bus bar 505 towards the bottom side 415. The vertical bus bars 540 can extend downwards towards a bottom row of trays 405. Bus bar portions 545 can extend perpendicularly from vertical bus bars 505 across a face of the trays 405. The bus bar portions 545 can be parallel with the horizontal bus bars 505 or the face of the trays 405. The bus bar portion 545 can be coupled with terminals 525 of resistive components 535 of the trays 405. The resistive components 535 can be electrical resistors that dissipate power received from the power source.

The resistive components 535 in a particular load bank module 105 can collectively dissipate 1 MW to 5.6 MW. Together, the resistive components 535 of multiple load bank modules 105 can dissipate up to 33.6 MW in an assembly where multiple load bank modules 105 are packed on one frame as one assembly. The resistive components 535 can collectively dissipate up to 67.2 MW in a system where two load bank assemblies are daisy chained together. The resistive components 535 of each load bank module 105 can collectively dissipate an amount of power, 3.5 MW to 4.5 MW, 3 MW to 5 MW, less than 3 MW, more than 5 MW, 1 MW to 5.6 MW, etc. The resistive components 535 of each load bank module 105 can collectively dissipate substantially 4 MW. The resistive components 535 of each load bank module 105 can collectively dissipate at least 4 MW. The resistive components 535 can each individually dissipate 18-20 kW. The resistive components 535 can each dissipate 17-20 kW. The resistive components 535 can each individually dissipate less than 17 kW. The resistive components 535 can each individually dissipate more than 20 kW. The power rating for the resistive components 535 can be configurable for different voltage ratings in the ranges of 480 to 15,000 volts or 480 to 33,000 volts. The resistive components 535 can have different steps as a single coil resistor value, or up to six steps. The surface operating temperature of the resistive components 535 can be up to 1,000 degrees Celsius.

The bus bar portions 545 can extend across a row of a resistive components 535 in one tray 405. The bus bar portion 505 can extend across a top row, middle row, or bottom row of resistive components 535 of a tray 405. The resistive components 535 can have a power density of 7-7.8 kW/f t³. The resistive components 535 can have a power density of 6.8-8 kW/ft³. The resistive components 535 can have a power density of less than 6.8 kW/ft³. The resistive components 535 can have a power density of greater than 8 kW/f t³. The resistive components 535 can provide 0.4-0.7 kW/lb. The resistive components 535 can provide 0.3-0.8 kW/lb. The resistive components 535 can provide less than 0.3 kW/lb. The resistive components 535 can provide more than 0.8 kW/lb.

In FIG. 5A, the bus bar portions 505 can extend across a top row of resistive components 535 for top and bottom rows of the trays 405. Because the horizontal bus bar 505, the vertical bus bar 540, and the bus bar portion 545 are electrically coupled with each other, the resistive components 535 can be electrically coupled to a neutral connection.

The bus bars 510, 515, and 520 can be electrically coupled to different phases of a power source. For example, the bus bar 510 can be coupled to a first phase of the power source, the bus bar 515 can be electrically coupled with a second phase of the power source, and the bus bar 520 can be electrically coupled with a third phase of the power source. The bus bars 510, 515, and 520 can be horizontal or parallel with the top side 415, the bottom side 415, or the horizontal bus bars 505. Each phase can be 40-1,600 amperes (at 33,000 volts to 480 volts for 1.3 MW).

The bus bar 510 can extend across a row of resistive components 535. For example, the bus bar 510 can extend over a bottom row of resistive components 535 of a bottom tray 405 of a first or leftmost column of trays 405. The bus bar 510 can be electrically coupled with terminals 525 of the row of resistive components 535. The bus bar 515 can extend across a row of resistive components 535. For example, the bus bar 515 can extend over a bottom row of resistive components 535 of a bottom tray 405 of a second or middle column of trays 405. The bus bar 515 can be electrically coupled with terminals 525 of the row of resistive components 535. The bus bar 520 can extend across a row of resistive components 535. For example, the bus bar 520 can extend over a bottom row of resistive components 535 of a bottom tray 405 of a third or rightmost column of trays 405. The bus bar 530 can be electrically coupled with terminals 525 of the row of resistive components 535. Vertical bus bars 550 can extend from each respective bus bar 510, 515, and 520. Horizontal bus bars 555 can extend horizontally from each vertical bus bar 550 to couple with terminals 525 of a row of resistive components 535 in each tray 405.

In FIG. 5A, the trays 405 of each respective column of trays 405 can be coupled in parallel. The trays 405 of a first column can be coupled in parallel with each other. The trays 405 of a second column can be coupled in parallel with each other. The trays 405 of a third column can be coupled in parallel with each other. In each tray 405, the resistive components 535 can be coupled in parallel and in series via bus bars 530. Each column of resistive components 535 in a particular tray 405 can be connected in series, while each column of resistive components 535 in the particular tray 405 can be coupled in parallel with each other column of resistive components 535. Each column of resistive components 535 can be electrically coupled between a bus bar coupled with a first phase of the power source to a bus bar coupled with a neutral of the power source.

Each column of trays 405 can include at least one temperature sensor and/or pressure sensor at the top of the column (e.g., near the exhaust louvers 145) and at least one temperature and/or pressure sensor at the bottom of column. Each column of trays 405 can include a top tray 565 positioned on the top of the column of trays 405. The top trays 565 can include neutral connections C4, which may be 250 amp 12 mm diameter copper rods. Furthermore, the top trays 565 can include temperature sensors T1 and pressure sensors P1. The temperature sensors T1 can be RTDs or any other type of temperature sensors. The temperature sensors T1 can have a body. The body can have a cylindrical or tubular shape. The body of the temperature sensors T1 can extend through openings in a lateral side of the tray 565. The openings can be circular or cylindrical shaped openings. The temperature sensors T1 can extend between the front sides and the rear sides of the tray 565. The temperature sensors T1 can extend from the front sides towards the rear sides of the tray 565. The temperature sensors T1 can extend from the rear sides towards the front sides of the tray 565. The temperature sensors T1 can be electrically coupled or connected with a controller of the load bank module 105 in which the tray 565 is installed.

The temperature sensors T1 can include at least one sensing element or component disposed in or along the body of the sensor 655. The sensing element or component can measure temperature. For example, the sensing component can be a thermocouple, a resistance temperature detector (RTD), a thermally sensitive resistor (thermistor), a negative temperature coefficient thermistor, or any other type of temperature sensor. The sensing components can include a pressure sensor. The temperature sensors T1 can include both a temperature sensing component and a pressure sensing component. The sensing components can be humidity, airflow, or any other kind of sensor that measures a characteristic or environmental condition of or within the tray 565, a column of trays 405 which the tray 565 is positioned above, or the load bank module 105. The sensing components of the temperature sensors T1 can be electrically coupled with a controller of the load bank module 105. The controller can measure the environmental characteristic or condition of a column of trays 405. The temperature sensors T1 can electrically communicate, provide, or transmit signals, values, or data indicating the environmental characteristic or condition to the controller.

Furthermore, the top trays 565 can include pressure sensors P1. The pressure sensors P1 can be pressure sensors to detect a pressure differential between each top tray 565 and bottom tray 560. For example, the pressure sensors of the top trays can measure a allow side, while the pressure sensors of the bottom trays can measure a high side. Furthermore, the top trays 565 can include an infrared probe. The pressure sensors P1 can be electrically coupled with a controller of the load bank module 105. The controller can measure the air pressure of a column of trays 405. The temperature sensors P1 can electrically communicate, provide, or transmit signals, values, or data indicating the environmental characteristic or condition to the controller.

Each column of trays 405 can include a bottom tray 560 positioned at the bottom of the column of trays 405. The bottom trays 560 can include cable passe throughs C1, which can be 50 millimeter mica tubes. Furthermore, each bottom tray 560 can include a temperature sensor T1 (similar or the same as the temperature sensor T1 of the top tray 565) and a pressure sensor P1 (e.g., a high side pressure). Each bottom tray 560 can include tubes C2 and C3, which can be mica tubes for 12 millimeter diameter dropper bars from the fuses 1705. The bottom trays 560 can include access panels 570.

Referring now to FIGS. 5B-5C, an example bottom tray 560 is shown. FIG. 5B illustrates a bottom tray 560 for a first load bank module 105, e.g., the first load bank module 105 105 directly coupled to the transformer module 225. FIG. 5C illustrates a bottom tray 560 for a subsequent land bank, e.g., one or more load banks coupled with the first load bank or another load bank instead of being directly coupled with the transformer module 225. The bottom tray 560 can include at least one jumper bus bar 580. For example, a jumper bus bar 580 can connect connection C3 to the bus bar 510 (which can be a particular phase bus bar). Furthermore, a bus bar 580 can connect connection C2 to the bus bar 550 (which can also be a bus bar for the particular phase). A ring 585 (e.g., a copper distance ring) can connect different sections of the bus bar 510 together. The ring 585 can be coupled with the different sections of the bus bar 510 via washers, nuts, etc. In FIG. 5C, an extra jumper 580 can be included to couple the bus bar 510 to the bus bar 550 though a ring, e.g., via a copper distance ring coupled to the bus bar 510 and bus bar 550 via at least one nut, bolt, or washer.

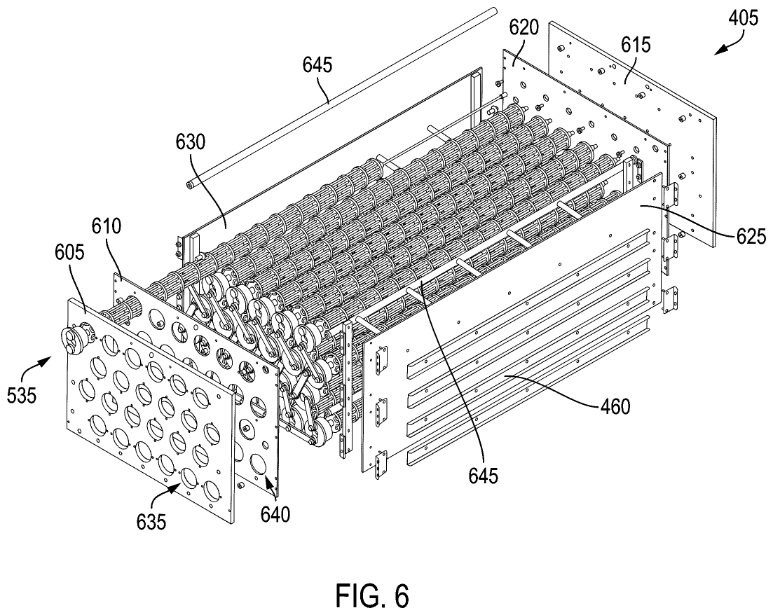

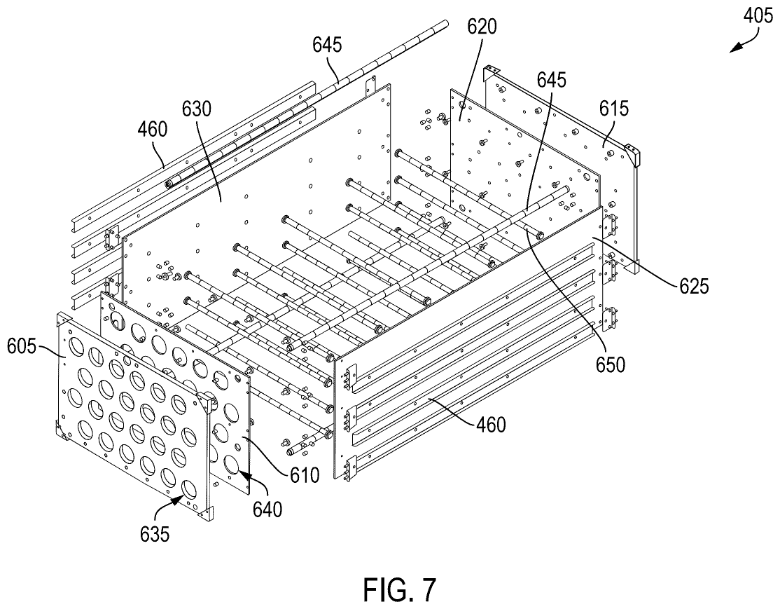

Referring now to FIGS. 6-7, among others, a tray 405 including resistive components 535 is shown. The tray 405 can include multiple lateral walls, sides, or surfaces, e.g., front sides 605 and 610, rear sides 615 and 620, and lateral sides 625 and 630. The sides of the tray 405 can form a prismatic shape, a rectangular solid shape, a cub shape, or any other type of shape. The tray 405 may not include any top or bottom side, to allow air to pass through the tray 405 to cool the resistive components 535. In some implementations, the tray 405 can include top or bottom sides. The front sides 605 and 610 can be disposed opposite the rear sides 615 and 620. The sides 605, 610, 615, and 620 can be parallel with one another. The sides 630 can be disposed opposite sides 625. The sides 625 and 630 can be parallel with each other. The sides 625 and 630 can be perpendicular with the sides 605, 610, 615, and 620.

The sides of the tray 405 can be formed from mica, such as dioctahedral mica, tetrahedral mica, trioctahedral mica, or interlayer-deficient mica. Any use of mica herein, in some implementations, can be dioctahedral mica, tetrahedral mica, trioctahedral mica, or interlayer-deficient mica. Because the sides of the tray 405 are formed of mica, and can remain stable at temperatures up to 500-900 degrees Celsius, the resistive cartridges 535 can dissipate heat without the tray 405 losing its structure or allowing a limited amount of bending or flexing. Because the tray 405 can be exposed to high temperatures without losing its form, the load bank 100 can dissipate high amounts of power (10 MWs, 20 MWs, etc.). The sides of the tray 405 can be formed from mica and can have a thickness of approximately 1 inch (25.4 millimeters). The thickness of the mica in the sides of the tray 405 can be 25-26 millimeters. The thickness of the mica in the sides of the tray 405 can be 24-27 millimeters. The thickness of the mica in the sides of the tray 405 can be 23-28 millimeters. The thickness of mica used in the sides can help sustain higher temperatures, and allow for the trays 405 to be rated up to 15,000 volts. By using mica of approximately 1 inch thickness, the tray 405 can reach higher temperatures, compared to other designs with may utilize metal sides of approximately ⅛^{th} inch.

The tray 405 can include at least one support 645 and at least one support 650. The supports 645 and 650 can be cylindrical shaped or tubular shaped components. The supports 645 and 650 can be formed from aluminum, steel, or mica. The supports 645 can couple with the front sides 605 or 610. A first end of the supports 645 can couple with the front sides 605 or 610. The supports 645 can couple with the back sides 620 or 615. A second end of the supports 645, opposite the first end, can couple with the back sides 620 or 615. The supports 645 can extend between the front sides 605 and 610 and the back sides 620 or 615. The supports 650 can couple with the lateral sides 625 or 630. A first end of the supports 650 can couple with the lateral side 625. A second end of the supports 650, opposite the first end, can couple with the side 630. The supports 650 can extend between the side 630 and 625.

The front sides 605 and 610 can include openings 635 and 640. The openings 635 and 640 can be circular or cylindrical shaped openings. The opening 635 and 640 can have circular shaped openings to allow a cylindrical shaped resistive component 535 to pass through the openings 635 and 640. However, the openings 635 and 640 can be rectangular shaped, square shaped, or triangular shaped to allow a resistive component 535 with a rectangular, square, or triangular cross-section to pass through the openings 635 and 640. The openings 635 and 640 can have diameters the same as, or greater than, the diameter of the resistive components 535. The resistive components 535 can insert through the openings 635 and 640 to install or uninstall from the tray 405. For example, the resistive components 535 can be inserted through the openings 635 and 640 from a first side of the sides 605 and 610 to a second side of the sides 605 and 610, opposite the first side. The resistive components 535 can insert or be pushed from a first or outer side, through the openings 635 and 640, into a body, cavity, space, or area of the trays 405. Furthermore, the resistive components 535 can exit or be pulled from the trays 405 through the openings 635 and 640. The trays 405 can provide continuous guided support for the resistive components 535 to be removed, e.g., pulled out, and installed, e.g., pushed in. The resistive components 535 can be partially or fully removed from a tray 405 and can be continuously supported as the components 535 are removed. The resistive components 535 can be removed or installed individually. For example, a service technician or other user can remove and replace a single resistive component 535. The service technician can remove and replace one or multiple resistive components 535 from a tray 405 individually without uninstalling other resistive components 535 or uninstalling the tray 405 from the load bank module 105.

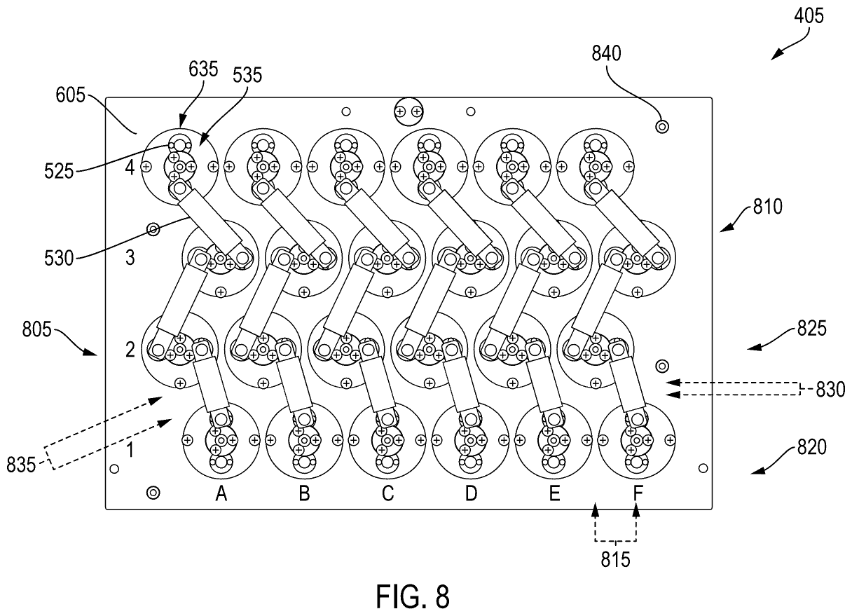

Referring now to FIG. 8, among others, is a tray 405 including bus bars 530 to form a circuit with resistive components 535. At least a portion of the resistive components 535 can be disposed within the tray 405, e.g., on an inner side of the side 605. Furthermore, at least a portion of the resistive components 535 can be disposed on an outer side of the side 605. The terminals 525 can be disposed or accessed on an outer side of the side 605. For example, at least a portion of the terminal 525 can be disposed on an outer side of the side 605. The bus bars 530 or the bus bars 510, 515, 520, or 545 can couple the resistive components on the outer side of the side 605. In this regard, the front outer side of the tray 405 can be a wiring board or area where a technician or assembly apparatus can wire the resistive components 535 together.

For example, the trays 405 can allow for configuration of wiring or connecting the resistor cartridges 535 installed in the trays 405. For example, the trays 405 can be configurable for resistor cartridges 535 in series and/or parallel. For example, the trays 405 can be configurable to have resistor cartridges 535 in twenty four parallel paths or multiple parallel paths with some cartridges 535 in series. This configurability can allow for an improvement or optimization of watt per square inch power at the resistor coil surface, and a reduction in resistor coil surface operating temperature. The trays 405 can have configurability in order to operate at any one selected and configured operating voltage in the range of 480 to 15,000 volts, for example, 480 volts, 4160 volts, 10,000 volts, 11,000 volts, 13,800 volts, etc.

The front side 605 can include multiple openings 635. The openings 635 can be organized in rows of openings. There can be one, two, three, four, or any number of rows of openings 635. The rows of openings 635 can be offset from one another. Some rows of the openings 635 can be offset, while other row of openings 635 may not be offset. This can form a zig-zag pattern. For example, alternative rows of openings 635 can be offset, e.g., a first row of openings not offset, a second row of openings 635 offset, a third row of openings not offset, and a fourth row of openings offset. The offset rows can be offset a distance 815 towards an outer edge of the side 605, for example, a left edge 805 or a right edge 810. For example, a first row 820 of openings 635 can be shifted a distance 815 away from being centered with another second row 825 above or below the first row 820, towards the edge 810. The distance 815 can be 500-510 millimeters. The distance 815 can be 490-520 millimeters. The distance 815 can be less than 490 millimeters. The distance 815 can be greater than 520 millimeters.

A line tangent with openings 635 of an upper side of the row 820 and a line tangent with openings 635 of the bottom side of the row 825 can be separated by a distance 830. The distance 830 can be approximately 412 millimeters (16.6 inches). The distances 830 can be 410-415 millimeters. The distance 830 can be 405-420 millimeters. The distance 830 can be less than 405 millimeters. The distance can be greater than 420 millimeters. A greatest or maximum distance between an outer side of an opening 635 of the first row 820 and an outer side of an opening 635 of a second row 825 (which both include resistive components 535 electrically coupled via a bus bar) can be a distance 835. The distance 835 can be approximately 671 millimeters (26.41 inches). The distance 835 can be 665-675 millimeters. The distance 835 can be 660-680 millimeters. The distance 835 can be less than 660 millimeters. The distance 835 can be greater than 680 millimeters.

The tray 405 can include a ground connection 840. The ground connection 840 can be electrically coupled with the earth. The ground connection 840 can provide a low resistance or impedance path to the earth.

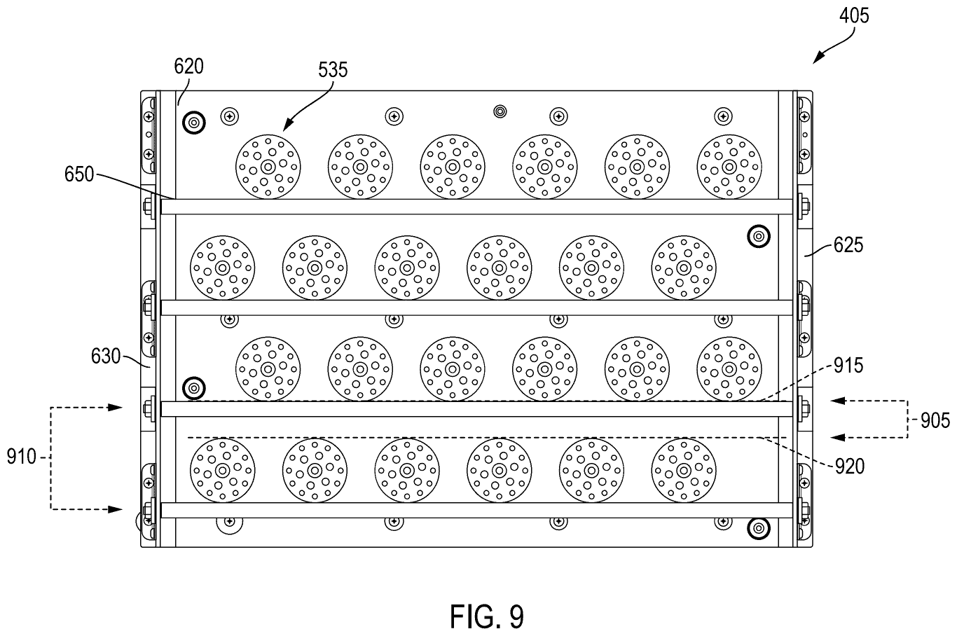

Referring now to FIG. 9, among others, a cross-section view of a tray 405 including resistive components 535 is shown. FIG. 9 illustrates an inner space of the tray 405. The supports 650 can extend between the lateral sides 625 and 630. First ends of the supports 650 can be coupled with the lateral side 630. Second ends of the supports 650 can be coupled with the lateral side 625. The supports 650 can be perpendicular to the lateral sides 625 and 630. The supports 650 can be spaced from each other a distance 910 in a direction parallel with the surfaces of the lateral sides 630 and 625. The distance 910 can be 200 millimeters. The distance 910 can be 198-202 millimeters. The distance 910 can be 196-204 millimeters. The distance 910 can be less than 196 millimeters. The distance 910 can be greater than 204 millimeters.

The bodies of the resistive components 535 can be spaced a distance 905. For example, a line 915 tangent to the bottom sides of the cylindrical bodies of a row of resistive components and a line 920 tangent to upper sides of the cylindrical bodies of another row of resistive components 535 immediately below the first row, can be spaced the distance 905. The distance 905 can be 92-94 millimeters. The distance 905 can be 91-95 millimeters. The distance 910 can be less than 91 millimeters. The distance 910 can be greater than 95 millimeters.

As shown in FIG. 9, each tray 405 can include multiple resistive cartridges 535. Each cartridge 535 can be removable from the load bank module 105 without removing the tray 405. Furthermore, each cartridge 535 can be individually removable without needing to remove another cartridge 535. As shown in FIG. 9, the tray 405 can include 24 cartridges. However, the trays 405 can each include 23-25 cartridges, 22-26 cartridges, less than 22 cartridges, more than 26 cartridges, etc.

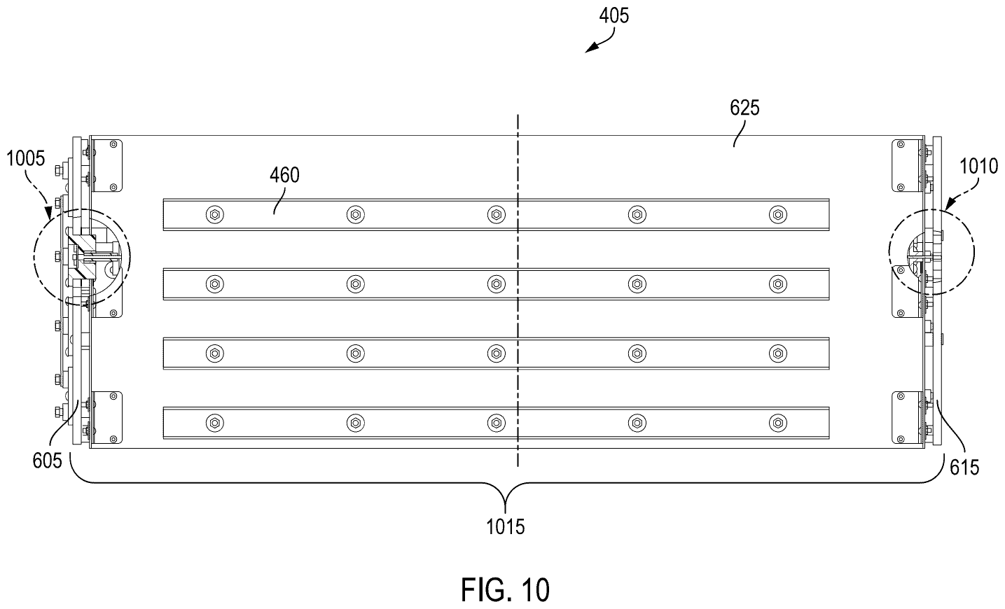

Referring now to FIG. 10, among others, a side view of a tray 405 including rails 460 to install or uninstall from a load bank module 105. The tray 405 can include one, two, three, four, or more rails 460 that extend from a front side 630 towards a rear side 625. A view 1005 can illustrate a connection between one resistive component 535 and the side 630. A view 1010 can illustrate a connection between the resistive component 535 and the side 625. The tray 405 can have a length 1015. The length 1015 can be 2.1-2.3 meters. The length 1015 can be 2.0-2.4 meters. The length 1015 can be less than 2.1 meters. The length 1015 can be greater than 2.4 meters.

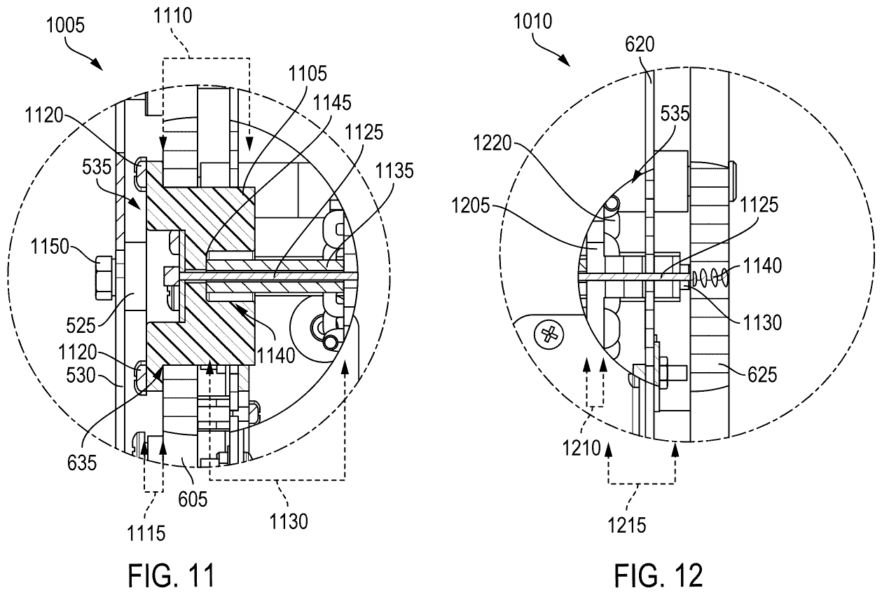

Referring now to FIG. 11, among others, the example view 1005 of a tray 405 where a resistive component 535 couples with a front lateral side of the tray 405. The resistive component 535 can include a front portion, apparatus, device, or head 1105. The head 1105 can be disposed in an opening 635 of the front portion 605. The head 1105 can include a first portion 1110 and a second portion 1115. The first portion 1110 of the head 1105 can extend into and through the opening 635 of the lateral side 605. The first portion 1110 can have a cylindrical or tubular shape.

The head 1105 can include a second portion 1115. The second portion 1115 can be disposed on an outer surface of the side 605. The second portion 1115 can be a cylindrical or tubular shape. A diameter or radius of the portion 1115 can be greater than the diameter or radius of the opening 635. In this regard, when the resistive component 535 is installed in the tray 405, the portion 1115 can come into contact with an outer surface of the side 605 around the opening 635, and stop or limit movement of the resistive component 535 as the resistive component 535 is inserted or installed in the tray 405. The resistive component 535 can include at least one connector 1120. The connectors 1120 can be screws, bolts, nails, snaps, or other components inserted through the portion 1115 of the head 1105 and into the lateral side 605.

The resistive component 535 can include at least one connector 1150. The connector 1150 can insert into or through a bus bar 530 into the terminal 525. The terminal 525 can include a threaded opening or space that the connector 1150 can couple into via threads on the connector 1150. The connector 1150 can be a nut, screw, bolt, nail, or any other connecting apparatus. The resistive component 535 can include a guide pin or guide rod or support member 1125. The support member 1125 can be disposed within a housing, case, jacket, or insulator 1135. The insulator 1135 and the support member 1125 can insert into a cavity 1143 of the second portion 1115. The cavity 1143 can be a cylindrical shaped cavity. A distance 1130 can extend from an inner surface or end 1145 of the cavity 1143 to a body or resistive coils of the resistive component. The distance 1130 can be 45-55 millimeters. The distance 1130 can be 40-60 millimeters. The distance 1130 can be less than 40 millimeters. The distance 1130 can be greater than 60 millimeters.

Referring now to FIG. 12, among others, an example view 1010 of a tray 405 where a resistive component 535 couples with a rear lateral side 625 of the tray 405. The resistive component 535 can include a rear end 1205. The rear end 1205 can be a washer, cap, apparatus, or device. The rear end 1205 can be formed from or include mica. The rear end 1205 can include a first portion 1210 and a second portion 1215. The first portion 1210 and the second portion 1215 can be integrally formed or can be separately joined or coupled components. The portion 1210 and the second portion 1215 can be cylindrical shaped components. The first portion 1205 can include circular openings for coils 1220 of wire to pass through. The second portion 1215 can extend from the first portion 1205, through an opening in the side 620, and towards or to the side 625. The support member 1125 can extend through the first portion 1205 and the second portion 1225 through a channel, opening, or space of the rear end 1205. The support member 1125 can extend to, into, or through a connector 1133. The connector 1133 can be a bolt, screw, threaded receiver, or magnetic coupling. A component 1140 can be inserted into or through the side 625. The component 1140 can be a threaded component, bolt, or screw that is part of or couples to the connector 1133. The connector 1133 and the component 1140 can couple the resistive component 535 with the side 625.

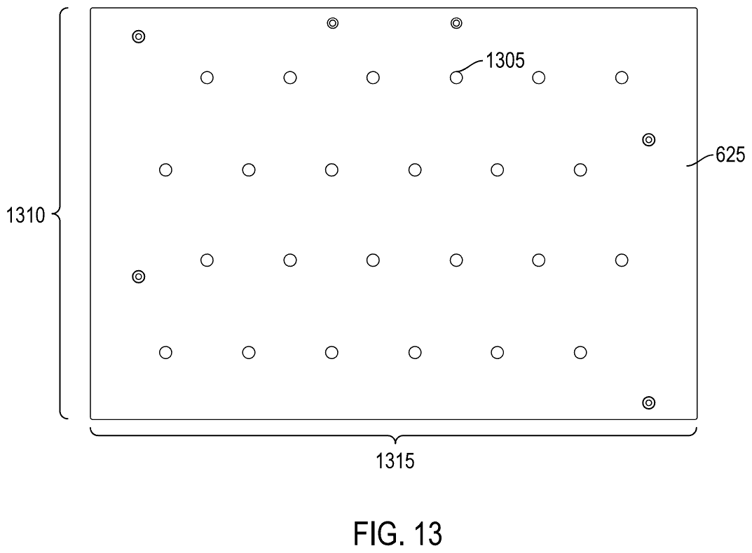

Referring now to FIG. 13, among others, a rear view of a tray 405 to install with a load bank module 105 is shown. The tray 405 can include openings 1305 on the rear side 625 which couple with the resistive components 535. The connectors, such as nuts, bolts, screws, snaps, or other connectors, couple the resistive components 535 with the side 625. The side 625 can have a width 1315. The side 625 can have a height 1310. The width 1315 and the height 1310 can be the width 1315 and height 1310 of the tray 405, and not just the side 625. The width 1315 can be 540-560 millimeters. The width 1315 can be 530-570 millimeters. The width 1315 an be less than 530 millimeters. The width 1315 can be greater than 570 millimeters.

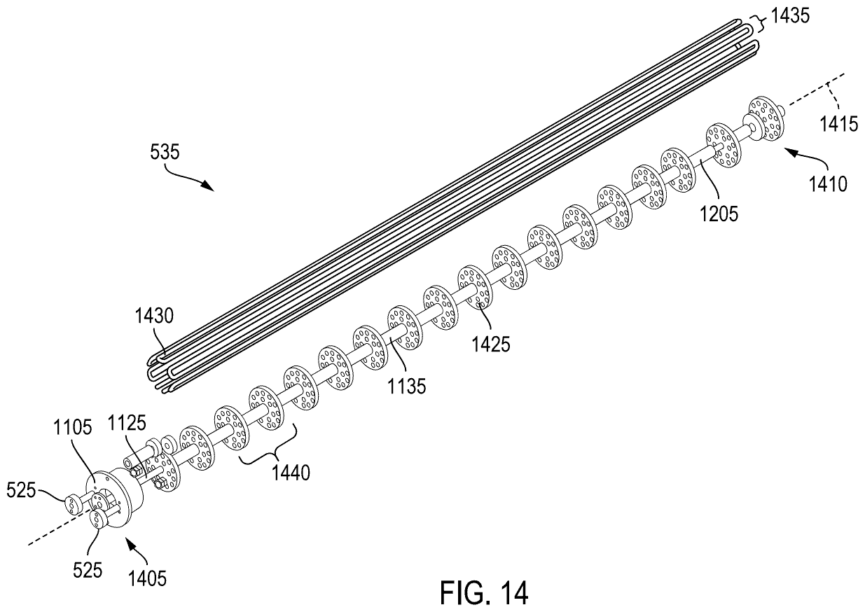

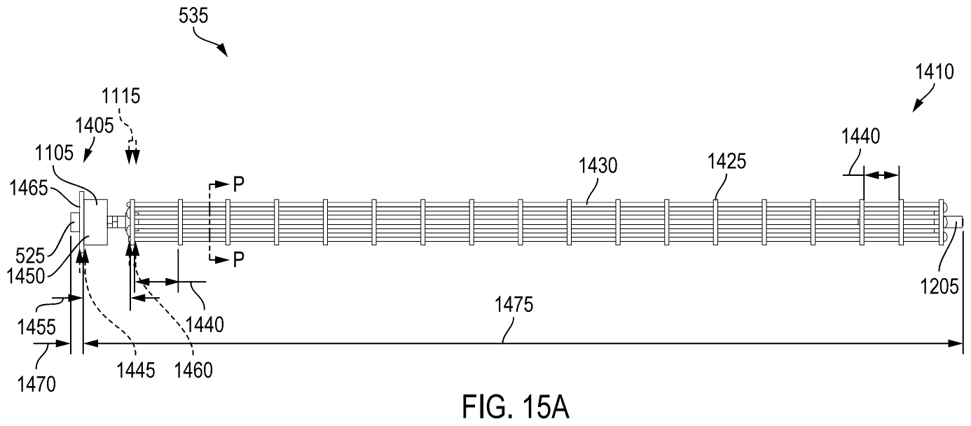

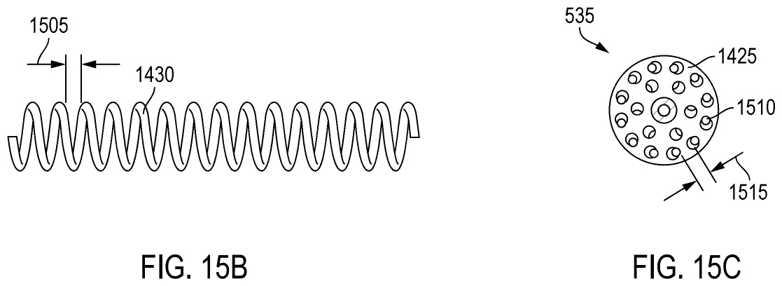

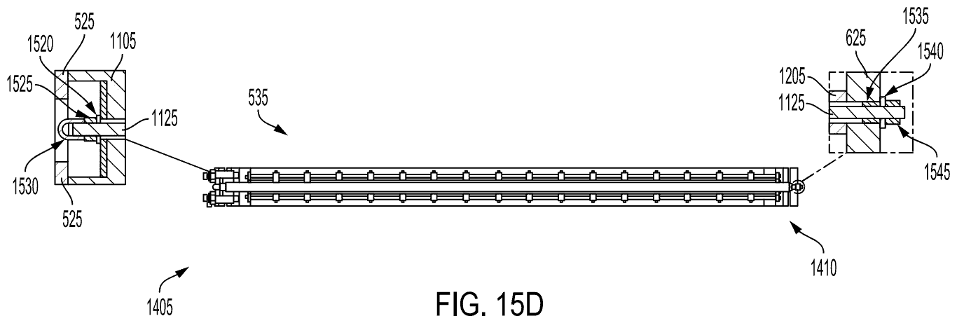

Referring now to FIGS. 14-15D, among others, a resistive component 535 including turns 1435 of wire 1430. The resistive component 535 can include terminals 525. The terminals 525 can be electrically coupled via bus bars with other resistive components 535, with a phase of the power source, or with a neutral of the power source. The terminals 525 can be electrically coupled or connected with wire 1430. The wire 1430 can be shaped in a coil, spring, or spiral pattern (e.g., as shown in FIG. 15B). Each ring of the spiral of the wire 1430 can be separated a distance 1505 from another ring of the coil of the wire 1430. For example, the distance 1505 can be between outer diameters of each ring of the spiral, and can be approximately 1.5 millimeters. The wire 1430 can be or include a Kanthal, Nikrothal, or other type of material. The wire 1430 can have a diameter of 0.8-0.9 millimeters. The wire 1430 can have a diameter of 0.75-0.95 millimeters. The wire 1430 can have a diameter less than 0.75 millimeters. The wire 1430 can have a diameter greater than 0.95 millimeters. The coiled wire 1430 can bend upwards, downwards, or sideways to allow for expansion due to increased temperature. The resistive component 535 may not include conventional springs to allow for temperature based expansion, and therefore can avoid having a short electrical path to ground for high voltage to jump to from one coil to another.

The resistive component 535 can have a first surface, end, or side 1405 and a second surface, end or side 1410. The first side 1405 and the second side 1410 can be opposite one another and located at either end of a length of the resistive component 535. The first side 1405 can be a front side defined by the head 1105. The second side 1410 can be a rear side defined by the end 1410.

The wire 1430 can extend back and forth between the first side 1405 of the resistive component 535 and the second side 1410 of the resistive component 535. The wire 1430 can extend from the first side 1405 to the second side 1410 or from the second side 1410 to the first side 1405 in a direction parallel with the longitudinal axis 1415 of the resistive component 535. The wire 1430 can extend back and forth between the first side 1405 and the second side 1410 in a spiral pattern, corkscrew pattern, coil pattern, or spring pattern (e.g., as shown in FIG. 15B). The wire 1430 can extend from the first side 1405, to the second side 1410, and back to the first side 1405 to form turns 1435 of the resistive component 535. The wire 1430 can extend back and forth between the first side 1405 and the second side 1410 to form multiple turns 1435. Each turn 1435 can be a length of the wire 1430 extending from one of side to the other (e.g., from first side 1405 to second side 1410, or from second side 1410 to first side 1405). The resistive component 535 can include 10-13 turns 1435. The resistive component 535 can include 9-14 turns 1435. The resistive component 535 can include less than 9 turns 1435. The resistive component 535 can include more than 14 turns 1435. The resistive component 535 can include 12 turns 435.

The resistive component 535 can include at least one disc 1425. The disc 1425 can be a washer or spacer. The disc 1425 can be formed from or include mica. The disc 1425 can be formed from electrically non-conductive material such as mica, ceramic, etc. Because the disc 1425 is non-conductive, the disc 1425 can provide electrical isolation and can be used at high temperature operation (600 to 1000 deg C.). The disc 1425 can have a cylindrical or disc shape. The discs 1425 can be disposed along a longitudinal axis 1415. The discs 1425 can be disposed between the first side 1405 and the second side 1410. The discs 1425 can be spaced from each other a distance 1440. The distance 1440 can be 60-65 millimeters. The distance 1440 can be 55-70 millimeters. The distance 1440 can be less than 55 millimeters. The distance 1440 can be greater than 70 millimeters. The discs 1425 can include openings, holes, or spaces for the wire 1430 to pass through. The openings can be circular, oval, or stadium shaped. For example, the discs 1425 can include openings for each turn 1435, a first opening of the wire 1430 to extend through where the wire 1430 extends from the first side 1405 to the second side 1410, and a second opening for the wire 1430 to extend through where the wire 1430 extends from the second side 1410 to the first side 1405. The wire 1430 can extend back and forth between the first side 1405 and the second side 1410 through the openings in the discs 1425. The wire 1430 can extend in a spiral pattern between the first side 1405 and the second side 1410. FIG. 15C illustrates the resistive component 535 along the cross-section P-P shown in FIG. 15A. In FIG. 15C, holes 1510 are shown in a disc 1425 (although each disc 1425 can have similar holes). The holes 1510 are separated a distance 1515. The distance 1515 can be approximately 9 millimeters.

The resistive component 535 can include the support member 1125. The support member 1125 can have a cylindrical, tubular, or rod shape. The support member 1125 can be a guiding inner rod for support and to assist with installation or removal of the resistive component 535 from the tray 405.

The support member 1125 can extend between the first side 1405 and the second side 1410. The support member 1125 can extend along the longitudinal axis 1415 of the resistive component 535. The support member 1125 can be centered on the longitudinal axis 1415. A length of the support member 1125 can be parallel with the longitudinal axis 1415. The support member 1125 can extend through openings in the discs 1425. The discs 1425 can be positioned such that circular surfaces of the discs 1425 are perpendicular with the longitudinal axis 1415. The discs 1425 can be centered on the longitudinal axis 1415, and an opening of the discs 1425 that the support member 1125 of each disc 1425 that the support member 1125 extends through can be centered on the longitudinal axis 1415. The centered openings of the discs 1425 can be circular in shape, and have a radius or diameter greater than a radius or diameter of a cross-section of the support member 1125.

The resistive component 535 can have a length 1475. The length 1475 can be a distance between the first side 1405 and the second side 1410. The length 1475 can be a distance from a surface 1450 of the second portion 1115 of the head 1105 to and end of the rear end 1205. The length 1475 can be 1240-1250 millimeters. The length 1475 can be 1230-1260 millimeters. The length 1475 can be less than 1230 millimeters. The length 1475 can be greater than 1260 millimeters. A distance 1455 between the surface 1450 of the second portion 1115 of the head 1105 and a first disc 1425 (or a disc 1425 closest to the first side 1405) can be 65-70 millimeters. The distance 1455 can be 60-75 millimeters. The distance 1455 can be less than 60 millimeters. The distance 1455 can be greater than 75 millimeters. A distance 1470 between an end of the terminal 525 and the surface 1465 of the second portion 1115 of the head 1105 can be 14-15 millimeters. The distance 1470 can be 13-16 millimeters. The distance 1470 can be less than 13 millimeters. The distance 1470 can be greater than 16 millimeters.

The disc 1425 can have a thickness 1460. The thickness 1460 can be 6-7 millimeters. The thickness 1460 can be 5-8 millimeters. The thickness 1460 can be less than 5 millimeters. The thickness 1460 can be greater than 7 millimeter. A distance 1445 between a surface 1465 and the surface 1450 (e.g., a thickness of the second portion 1115) can be 6-7 millimeters. The distance 1445 can be 5.5-7.5 millimeters. The distance 1445 can be less than 5.5 millimeters. The distance 1445 can be greater than 7.5 millimeters.

In FIG. 15D, the resistive component 535 is an example cross-sectional view of the resistive component along a length of the resistive component. The support member 1125 can be threaded, or have at least one threaded end. The support member 1125 can extend from a first threaded end on a front side 1405 through the resistive component 535 to a second threaded end on a rear side 1410 of the resistive component 535. At the front side 1405, an end of the support member 1125 can extend through a surface in the head 1105, and can include an exposed portion that at least one washer 1520, lock nut 1525, or nut 1530 (e.g., dome nut) can be coupled. At the rear side 1410, an end of the support member 1125 can be threaded, and screw into or insert into a component 1535. The component 1535 can be embedded within the side 625. The component 1535 can be a wood insert nut. A washer 1540 can be disposed about the support member 1125 on an outer side of the side 625, and a nut 1545, such as a lock nut, can be coupled to the end of the support member 1125.

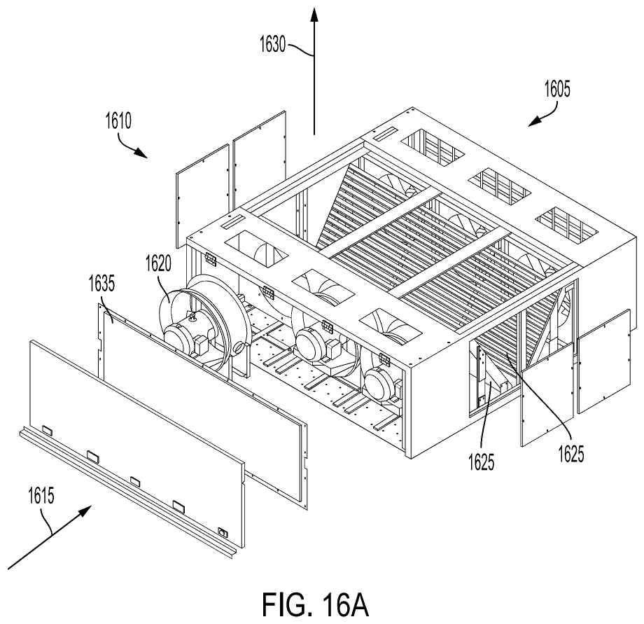

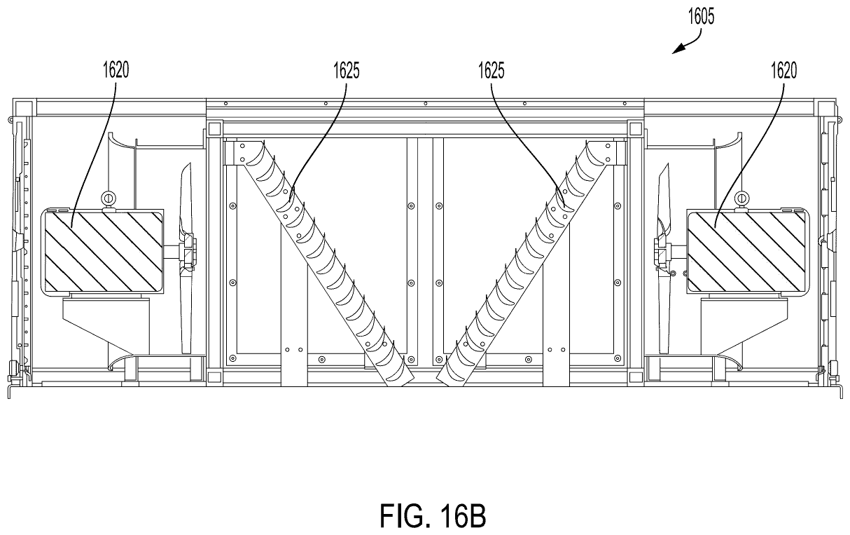

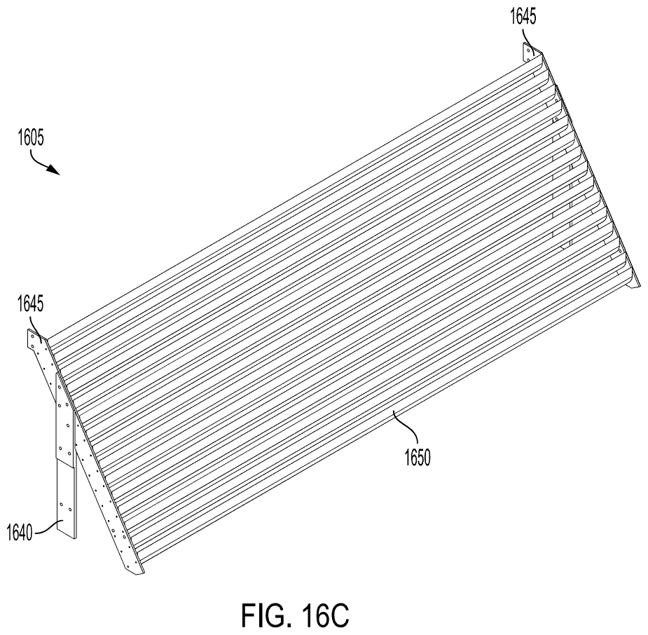

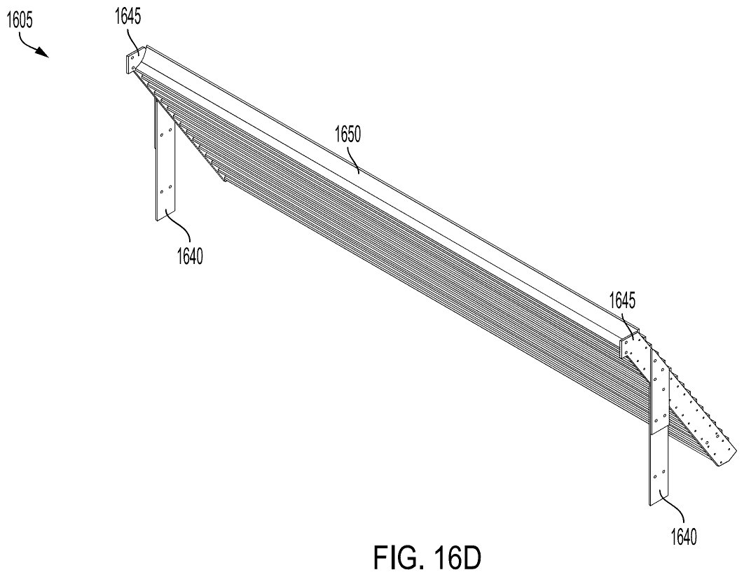

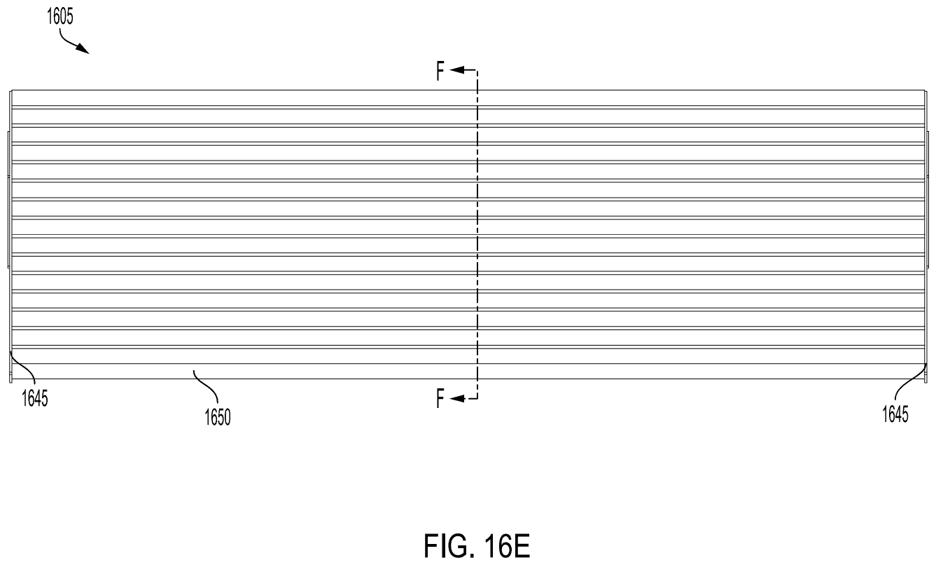

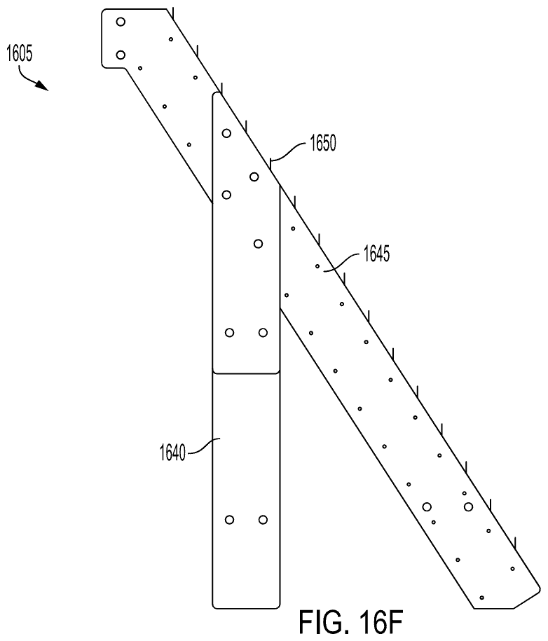

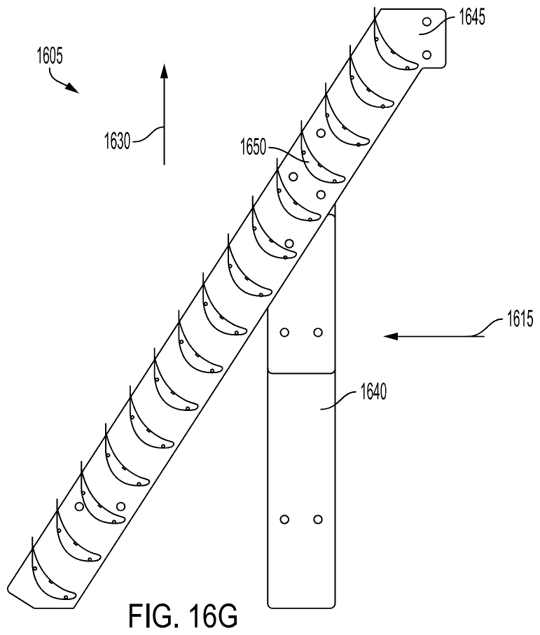

Referring now to FIGS. 16A-B, among others, a fan apparatus 1605 is shown. The fan apparatus 1605 can include at least one housing 1610. The housing 1610 can be formed from or include steel, aluminum, titanium, etc. The housing 1610 can be a bottom portion of a housing 115 of a load bank module 105. The housing 1610 can be disposed between a surface, such as the bed of a truck, the ground, pavement, concrete, and the housing 115 of the load bank module 105. The fan apparatus 1605 can be disposed between a bottom side, bottom surface, or bottom panel of a load bank module 105 and the trays 405 and resistive components 535 of the load bank module 105. Each load bank module 105, or at least one load bank module 105, can include a fan apparatus 1605. The fan apparatus 1605 can be disposed below the trays 405, the bottom trays 560, the resistive components 535, etc.

The fan apparatus 1605 can include an opening on a first side of the housing 1610 to draw air inwards along a first direction 1615. The fan apparatus 1605 can include at least one fan or blower 1620. The blowers 1620 can run to draw air along the direction 1615 into the housing 1610 through the opening in the side of the housing 1610. The fan apparatus 1605 can include at least one component, directional component, or air guide vane 1625. The air guide vane 1625 can be a wall, surface, or panel that directs air. The guide vanes 1625 can direct horizontal air flow to a 90° bend for vertical air flow, directed upward to the resistor trays 405. Two opposing horizontal air flows can be drawn in by the opposing blowers 1620, and directed upward vertically by the respective air guide vanes 1625 combine the air drawn in by the blowers 1620 into one air flow. This configuration can provide a more uniform vertical air flow to resistor coil 535 in trays 405 with reduce a pressure drop. Each of fan outlet air flows is guided through the guide vanes 1625 for a minimum or lower pressure drop and to reduce turbulence.

The air guide vane 1625 can direct air pulled in by the blowers 1620 upwards, along a second direction 1630. The air guide vane 1625 can direct air from a first direction 1615 ninety degrees to a second direction 1630. The directions 1615 and 1630 can be substantially perpendicular with each other. The directions 1615 and 1630 can form an angle between 85-95 degrees. The directions 1615 and 1630 can form an angle between 80-100 degrees. The directions 1615 and 1630 can form an angle less than 80 degrees. The directions 1615 and 1630 can form an angle greater than 100 degrees. The fan apparatus 1605 can include blowers 1620 on opposing sides facing each other (e.g., as shown in the cross-sectional view of FIG. 16B). The blowers 1620 can draw in air from opposing sides of the fan apparatus, and the air guide vanes 1625 can direct the air upwards towards the resistive components 535. A first air guide vane 1625 can redirect air drawn in by blowers 1620 on a first side of the fan apparatus 1605, while a second air guide vane 1625 can redirect air drawn in by blowers 1620 on a second opposite side of the fan apparatus 1605. The fan apparatus 1605 can provide air to cool resistive components 535 in one airflow duct, e.g., the fan apparatus 1605 can cool resistive components dissipating 4,000 kW in one airflow duct.

The blowers 1620 can pull the air from outside the load bank module 105 into the load bank module 105. The blowers 1620 can pull the air in the direction 1615 and through at least one screen 1635 of the fan apparatus 1605. The screen 1635 can be a mesh or a filter that prevents objects or particles from entering the load bank module 105. The air guide vane 1625 can direct the airflow away from a bottom of the load bank module 105 upwards towards the trays 405 or the resistive components 535. The airflow can pass over or through the trays 405 and over or through the resistive components 535. The airflow can cool the trays 405, the resistive components 535, or other components of the load bank module 105. The airflow can exit the load bank module 105 out the openings 125.

Referring now to FIGS. 16C-16F, among others, the air guide vane 1625 is shown. The air guide vane 1625 can include at least one vertical portion 1640. The air guide vane 1625 can include a vertical portion 1640 on opposing sides of the air guide vane 1625 which can support or couple the air guide vane 1625 to a bottom surface or side surface of the fan apparatus 1605. Each of the vertical portions 1640 can support an angled portion 1645. Each angled portion 1645 can be positioned parallel to one another. The air guide vane 1625 can include individual vanes 1650. The vanes 1650 can extend between the angled portions 1645. FIG. 16G depicts a cross-sectional view of the air guide vane 1625 along cross-section F-F of FIG. 16E. The vanes 1650 can be curved or have a concave inner surface to redirect air from an oncoming airflow from a direction 1615 to direction upwards 1630.

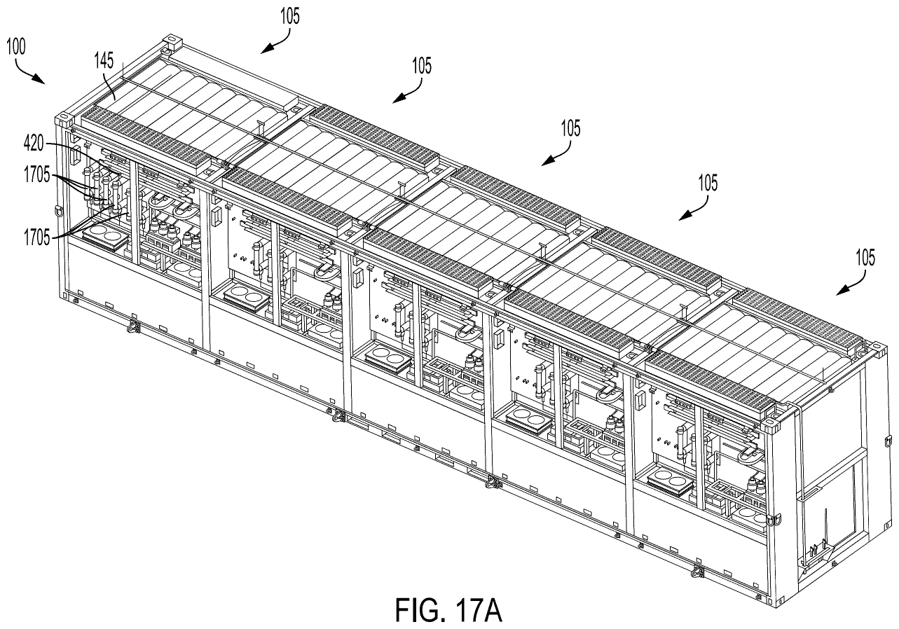

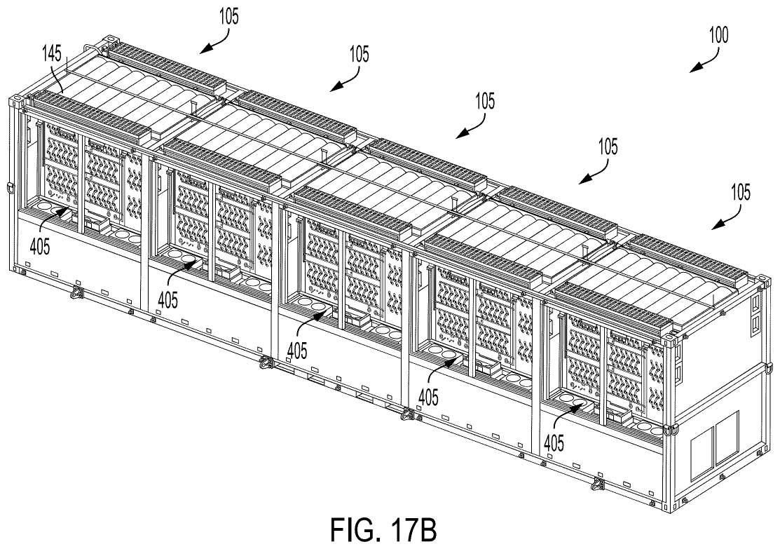

Referring now to FIG. 17A, among others, a high voltage side of load bank modules 105 including fuses 1705 is shown. The fuses 1705 can be devices that disconnect trays 405 or resistive components 535 from the power source. The fuses 1705 can disconnect or break a circuit or electrical connection between a power source and the trays 405 or resistive components 535 responsive to a level of current exceeding a threshold. Each load bank module 105 can include at least one fuse 1705. Each load bank module 105 can include at least three fuses 1705. A first end or terminal of the fuses 1705 can be coupled with a bus bar 420 that electrically couples the fuse 1705 with a set or group of trays 405. A second end or terminal of the fuses 1705 can be coupled, either directly or indirectly, with the power source, or with a particular terminal of the power source for a particular phase.

Each load bank module 105 can include a fuse 1705 to switch a different phase of the power source. For example, the load bank module 105 can include a first fuse 1705 in an electrical path between a first set of trays 405 and a first phase of the power source. The first fuse 1705 can disconnect the first set of trays 405 from the first phase of the power source responsive to the current of the first phase exceeding a threshold of the first fuse 1705. The load bank module 105 can include a second fuse 1705 in an electrical path between a second set of trays 405 and a second phase of the power source. The second fuse 1705 can disconnect the second set of trays 405 from the second phase of the power source responsive to the current of the second phase exceeding a threshold of the second fuse 1705. The load bank module 105 can include a third fuse 1705 in an electrical path between a third set of trays 405 and a third phase of the power source. The third fuse 1705 can disconnect the third set of trays 405 from the third phase of the power source responsive to the current of the third phase exceeding a threshold of the third fuse 1705.

Referring now to FIG. 17B, among others, an example view of a low voltage side of load bank modules 105 including trays 405 is shown. Each of trays 405 are exposed on a front side. Each load bank module 105 can include at least one stack of trays 405. Each stack of trays 405 can provide resistive components 535 for dissipating power of one phase of an AC source. For example, each load bank module 105 can include three stacks of trays 405.

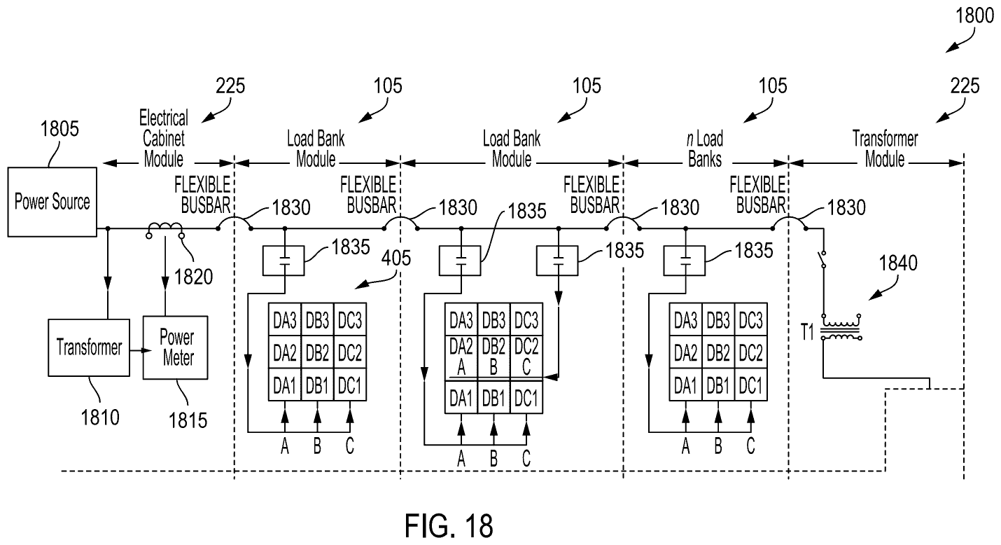

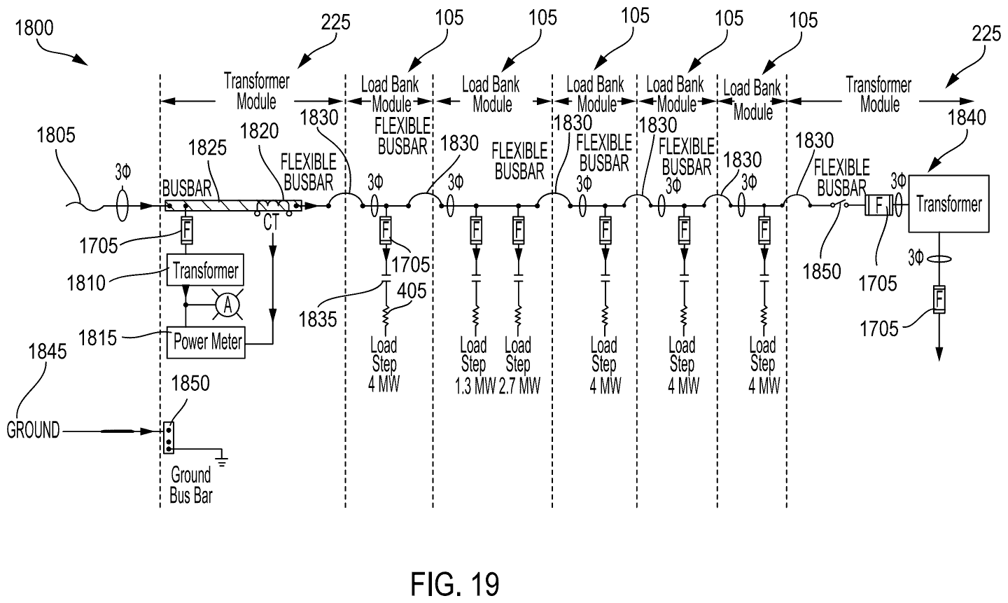

Referring now to FIGS. 18-19, among others, an example circuit 1800 of load bank modules 105 coupled with a power source 1805 is shown. The power source 1805 can be a generator system, a battery system, an uninterruptible power supply, a photovoltaic system, a turbine system, or any other power generating system, apparatus, or piece of equipment. The power source 1805 can provide 480 to 15,000 volts alternating current (AC) power. For example, the power source 1805 can provide 13,800 volts AC) power. The power source 1805 can provide 13,700-13,900 volts of AC power. The power source 1805 can provide 13,110-14,490 volt of AC power. The AC power can be 50 or 60 hertz power. The phases of the power source 1805 can be sinusoidal, and approximately 120 degrees out of phase with each other. The power source 1805 can include a ground 1845, that can be coupled with a ground bus bar 1850 of the load bank module 105.

The transformer module 225 can be electrically coupled via one, two, three, or multiple cables with the power source 1805. The transformer module 225 can include a transformer 1810 to step down the voltage from the power source 1805. The transformer 1810 can have a transformation ratio to step the voltage down to approximately 120 volts AC. The power meter 1815 can be a microcontroller, circuit board, or computing system that can measure the voltage of the power source 1805 via the voltage provided by the transformer 1810. The transformer module 225 can include a current transformer (CT) 1820. A coil of the CT 1820 can be disposed or wound about a bus bar 1825 coupled with the power source 1805. Current passing through the bus bar 1825 can induce a current in the coil of the CT 1820, which can be sensed or measured by the power meter 1815.

The power meter 1815 can measure voltage and current from the power source 1805. The power meter 1815 can use the voltage and current to determine power. The power meter 1815 can measure power from 0.5 to 35 MW. The power meter 1815 can measure power between 1-25 MW. The power meter 1815 can measure power less than 1 MW. The power meter 1815 can measure power greater than 25 MW.

The bus bar 1825 can be coupled with a first load bank module 105 via a flexible bus bar 1830. For example, the three phases of the power source 1805 can be coupled with the first load bank 105 via a first flexible bus bar 1830 while a second load bank module 105 can be electrically coupled with the first load bank module 105 and the power source 1805 via a second flexible bus bar 1830. The load bank modules 105 can be electrically coupled in parallel with one another and the power source 1805. The load bank modules 105 can be rated for voltages 480 to 15,000 volts. In this regard, the load bank modules 105 can couple directly with the power source 1805, instead of coupling to the power source 1805 through a stepdown transformer.

The load bank modules can include fuses 1705 between steps, disconnects, contactors, or switches 1835 and the three phases of the power source 1805. The load bank modules 105 can include a circuit or current path from a first phase of the power source 1805, through a first fuse 1705, through a first contactor 1835, and through a first set of trays 405 and resistive components 535. The load bank modules 105 can include a similar path for each phase. For example, the load bank modules 105 can include a circuit or current path from a second phase of the power source 1805, through a second fuse 1705, through a second contactor 1835, and through a second set of trays 405 and resistive components 535. Furthermore, the load bank modules 105 can include a circuit or current path from a third phase of the power source 1805, through a third fuse 1705, through a third contactor 1835, and through a third set of trays 405 and resistive components 535. The load bank modules 105 can include minimum steps 1835 of 1,000 KW to 1,300 KW. The load bank modules 105 can include maximum steps of 4,000 kW to 5,600 KW. The steps 1835 can be configurable, e.g., configured to 4,000 kW, 3,300 kW, 2,667 kW, 1,333 kW, 700 kW.

The first set of steps 1835 can electrically couple the phases of the power source 1805 with all of the trays 405 of the load bank module 105. The current from the first set of steps 1835 to the trays 405 can be approximately 55 amperes, e.g., 50-60 amperes. The current from the first set of steps 1835 to the trays 405 can be 45-65 amperes. The current from the first set of steps 1835 can be less than 45 amperes. The current from the first set of steps 1835 can be greater than 65 amperes.

The second set of steps 1835 can electrically couple the phases of the power source 1805 with a portion of the trays 405 of the load bank module 105. For example, each phase from the second set of steps 1835 can be electrically coupled with two trays 405. The current from the second set of steps 1835 to the trays 405 can be approximately 111 amperes, e.g., 100-115 amperes. The current from the second set of steps 1835 to the trays 405 can be 95-120 amperes. The current from the first set of steps 1835 can be less than 95 amperes. The current from the second set of steps 1835 can be greater than 120 amperes.

The transformer module 225 can be electrically coupled with the three phases of the power source 1805. The transformer module 225 can be electrically coupled with the three phases of the power source 1805 through electrical connections via bus bars or flexible bus bars 1830 of the load bank modules 105. The transformer module 225 can include a manual disconnect or switch 1850. The transformer module 225 can include at least one transformer 1840. The transformer 1840 can be a delta or star configured transformer. The transformer 1840 can transform a voltage of the phases of the power source 1805 to a voltage for components of the load bank 100 to operate on. For example, the transformer 1840 can convert a voltage from 13,800 volts AC to 480 volts AC. The transformed voltage can be used to operate various components of the load bank module 105, such as the blowers 1620, or any other electrically actuated component.

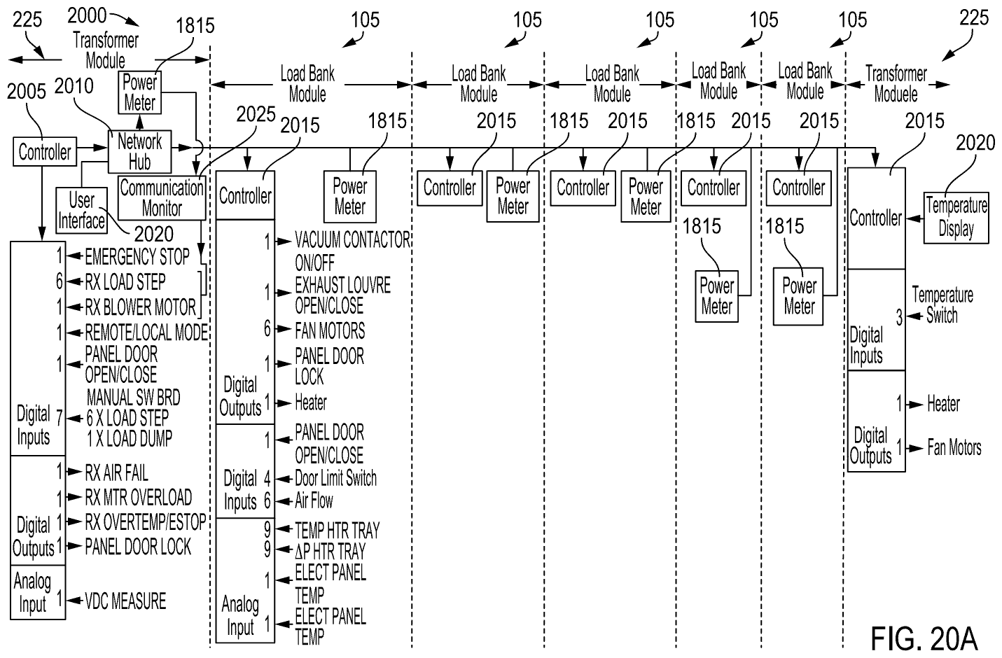

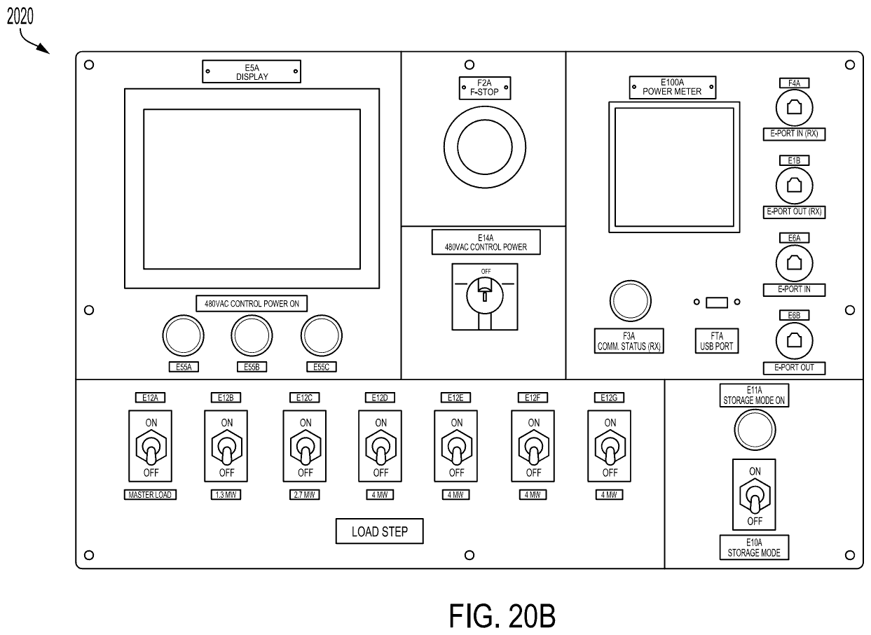

Referring now to FIGS. 20A-20B, among others, an example circuit 2000 of controllers of load bank modules 105 that control the load bank modules 105 is shown. The transformer module 225 can include at least one controller 2005. The controller 2005 can be electrically coupled with the network hub 2010 or can include the network hub 2010. The network hub 2010 can be electrically coupled with the controller 2005 of the transformer module 225 or the controllers 2015 of the load bank module 105. The controller 2005 and the controllers 2015 can be programmable logic controllers, computing systems, data processing systems, microcontrollers, or any other general purpose or specific purpose processing system. The controller 2005 can transmit control commands or control decisions to the controllers 2015. The controllers 2015 can transmit data, measurements, or other information to the controller 2005, and the controller 2005 can receive the data from the controllers 2015. The controller 2005 can cause, via communication through the network hub 2010, data to be displayed on the user interface 2020 (shown in FIG. 20B).

The transformer module 225 can include a user interface 2020. The user interface 2020 can be or include a light emitting diode (LED) display, a liquid crystal display (LCD), or an organic light emitting display (OLED). The user interface 2020 can be electrically coupled with the controller 2005 via the network hub 2010. The controller 2005 can cause the user interface 2020 to display information, measurements, or other data that the controller 2005 generates, calculates, or collects. For example, the controller 2005 can receive measurements from the power meter 1815 and cause the user interface 2020 to display the measurements.

The controller 2005 can include digital inputs. The digital inputs can include an emergency stop input. For example, responsive to receiving an indication to stop the load bank module 105 from a switch, lever, or other device, the controller 2005 can operate one or more switches or contactors to disconnect the load bank module 105 from the power source 1805. The controller 2005 can include inputs to receive signals from a load step, a blower motor, a model selection input device. The controller 2005 can include an input from a door switch that indicates whether the door of the transformer module 225 is open or closed. The controller 2005 can include manual switch inputs for load steps. The controller 2005 can include digital outputs. The digital outputs can be air fail outputs, overload outputs, overtemperature and emergency stop outputs, and door panel lock outputs to lock a door of the load bank module 105. The analog inputs of the controller 2005 can be a temperature measurement input.

The controllers 2015 can include digital outputs, digital inputs, and analog inputs for each respective load bank module 105. For example, the controllers 2015 can include a vacuum contactor output that the controller 2015 can turn on or off. The controllers 2015 can include fan motor outputs to turn on or off motors of the blowers 1620. The controllers 2015 can include a panel door lock output to lock or unlock the doors of the load bank modules 105. The controllers 2015 can include a heater output that the controller 2015 can turn on, or turn off, or adjust the level of heating provided by a heater of the load bank module 105. The controllers 2015 can include digital inputs that indicate whether a door is open or closed, a door limit switch, an air pressure meter. The controllers 2015 can include temperature input for each tray 405 of the load bank module 105, temperature differential, an electric panel temperature inputs. The transformer module 225 can include at least one controller 2015. The controller 2015 can include a temperature switch digital input. The controller 2015 can include digital outputs to operate a heater. The controller 2015 can include digital outputs to operate motors of the blowers 1620 of the load bank modules 105.

In some implementations, the controller 2015 can provide two channel power measurements of voltages from 80 to 600 volts AC and 8 to 15,000 volts DC. With an external power transformer, the controller 2015 can provide measurements from 600 to 15,000 volts AC. With an external current transformer, the controller 2015 can provide current measurements of 1 to 5 amperes. The controllers 2015 can measure AC signals of one, two, or three phases, measure power factor, or measure frequency of an AC signal (e.g., a 50 hertz AC signal, a 60 hertz AC signal, a 400 hertz AC signal). The controllers 2015 can provide control power and fan motor power monitoring. The controllers 2015 can measure low voltages and/or currents. The system can provide fan motor protection for unbalanced phases, loss of phases, overload current based on the frequency (e.g., 50 or 60 hertz) and motor parameters. The motor parameters can be self-tuning. The controller 2015 can find or record in an auto set up mode.

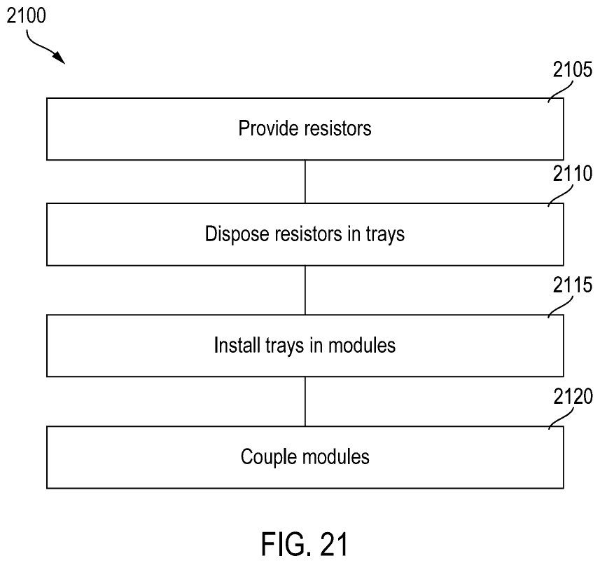

Referring now to FIG. 21, among others, an example method 2100 of providing a load bank 100 is shown. The method 2100 can be performed by a manufacturing system, manufacturing apparatus, a manufacturing individual, a technician, an installation service member, a robotic assembly system, or any other system, apparatus, or component. The method 2100 can include an ACT 2105 of providing resistors. The method 2100 can include an ACT 2110 of disposing resistors in trays. The method 2100 can include an ACT 2115 installing trays in modules. The method 2100 can include an ACT 2120 of coupling modules.

At ACT 2105, the method 2100 can include providing resistors 535. For example, the method 2100 can include manufacturing, assembling, or obtaining resistors 535 for installation with trays 405. The method 2100 can include providing a support member 1125 for the resistive component 535. The support member 1125 can have a cylindrical shape. The method 2100 can include providing a head 1105, which can define or be positioned on a first side 1405 of the cylindrical resistive component 535. The method 2100 can include coupling an end of the support member 1125 with the head 1105. For example, the support member 1125 can be inserted through an opening in the head 1105. The method 2100 can include providing the discs 1425, and machining, forming, or drilling holes in the discs 1425. The method 2100 can include disposing discs 1425 on the support member 1125. The discs 1425 can be spaced from a first end 1405 of the resistive component 535 to a second end 1410. The ACT 2105 can include providing windings or turns 1435. For example, the method 2100 can include coiling the wire 1430. The method 2100 can include passing the wire through the openings in the discs 1425 from the first end 1405 to the second end 1410 and from the second end 1410 to the first end 1405. The method 2100 can include coupling a first end of the wire 1430 with a first terminal 525 of the resistive component 535. The method 2100 can include coupling a second end of the wire 1430 with a second terminal 525.

At ACT 2110, the method 2100 can include disposing resistors 535 in trays 405. The method 2100 can include disposing the resistors 535 in the trays 405 to dissipate power received from the power source 1805. The resistors 535 can be formed to be removably coupled with the trays 400. The method 2100 can include drilling or forming holes or openings 635 in an opening in a side 605 of the tray 405. The method 2100 can include inserting the resistive components 535 through the openings 635 into the trays 405. The method 2100 can include coupling the head 1105 with the side 605. For example, a surface of a second portion 1115 of the head 1105 can couple with a surface of the side 605. Furthermore, connectors 1120 can couple the head 1105 with the side 605. The method 2100 can include coupling the rear end 1205 with the side 625 via connectors 1130 and 1140.

At ACT 2115, the method 2100 can include installing the trays 405 in the load bank modules 105. For example, the method 2100 can include disposing the trays 405 in a load bank module 105 to removably couple with the load bank module 105. The method 2100 can include disposing, coupling, or fixing at least one first rail 460 to an outer surface of the side 625 of the tray 405. The method 2100 can include disposing at least one second rail on an inner surface of the side 415. The method 2100 can include coupling the at least one first rail 460 with the at least one second rail of the load bank module 105. The method 2100 can include installing or uninstalling, via the first rail 460 and the second rail, the tray 405 with the load bank module 105. The method 2100 can include stacking the trays 405 in columns within the housing 410 of the load bank module 105. For example, the housing 410 can have sets of rails to allow the trays 405 to install in the load bank module 105 in columns and rows of trays 405. The method 2100 can include coupling a first set or column of trays 405 with a first phase of the power source 1805. The method 2100 can include coupling a second set or column of trays 405 with a second phase of the power source 1805. The method 2100 can include coupling a first set or column of trays 405 with a third phase of the power source 1805. For example, via bus bars 510, bus bars 550, and bus bars 555, a first set of trays 405 can be coupled with a first phase, a second set of trays 405 can be coupled with a second phase, and a third set of trays 405 can be coupled with a third phase.

The method 2100 can include coupling the load bank modules 105. For example, the method 2100 can include coupling the load bank modules 105 together. The method 2100 can include coupling at least one load bank module 105 with at least one other load bank module 105 to dissipate the power received from the power source 1805. The method 2100 can include coupling the load bank modules 105 in parallel with the power source 1805. A first load bank module 105 can be electrically coupled with the power source 1805 through an transformer module 225 of the load bank 100. A second load bank module 105 can be electrically coupled with the power source 1805 through electrical connections of the first load bank module 105. The method 2100 can include electrically connecting the load bank modules 105 with one another via flexible bus bars 1830, rigid bus bars, or cables.

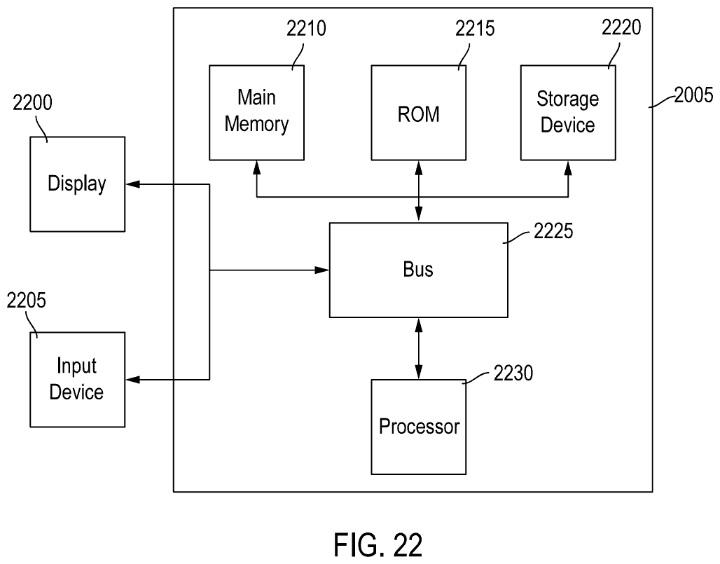

Referring now to FIG. 22, among others, an example computing architecture of a controller 2005 is shown. The architecture described in FIG. 22 can be used to implement the controller 2005, the network hub 2010, the power meter 1815, the user interface 2020, the communication monitor 2025, or the controller 2015. The controller 2005 can include at least one bus 2225 or other communication component for communicating information and at least one processor 2230 or processing circuit coupled to the bus 2225 for processing information. The controller 2005 can include one or more processors 2230 or processing circuits coupled to the bus 2225 for processing information. The controller 2005 can include at least one main memory 2210, such as a random access memory (RAM) or other dynamic storage device, coupled to the bus 2225 for storing information, and instructions to be executed by the processor 2230. The main memory 2210 can be used for storing information during execution of instructions by the processor 2230. The controller 2005 can further include at least one read only memory (ROM) 2215 or other static storage device coupled to the bus 2225 for storing static information and instructions for the processor 2230. A storage device 2220, such as a solid state device, magnetic disk or optical disk, can be coupled to the bus 2225 to persistently store information and instructions.

The controller 2005 can be coupled via the bus 2225 to a display 2200, such as a liquid crystal display, or active matrix display. The display 2200 can display information to a user. An input device 2205, such as a keyboard or voice interface can be coupled to the bus 2225 for communicating information and commands to the processor 2230. The input device 2205 can include a touch screen of the display 2200. The input device 2205 can include a cursor control, such as a mouse, a trackball, or cursor direction keys, for communicating direction information and command selections to the processor 2230 and for controlling cursor movement on the display 2200.

The processes, systems and methods described herein can be implemented by the controller 2005 in response to the processor 2230 executing an arrangement of instructions contained in main memory 2210. Such instructions can be read into main memory 2210 from another computer-readable medium, such as the storage device 2220. Execution of the arrangement of instructions contained in main memory 2210 causes the controller 2005 to perform the illustrative processes described herein. One or more processors in a multi-processing arrangement can be employed to execute the instructions contained in main memory 2210. Hard-wired circuitry can be used in place of or in combination with software instructions together with the systems and methods described herein. Systems and methods described herein are not limited to any specific combination of hardware circuitry and software.

Although an example computing system has been described in FIG. 22, the subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiations in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, Python, LAD, FBD, ST, IL, SFC or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices including cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. ACTs, elements and features discussed in connection with one implementation are not intended to be excluded from a similar role in other implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any ACT or element being based on any information, act or element may include implementations where the act or element is based at least in part on any information, act, or element.

Any implementation disclosed herein may be combined with any other implementation or example, and references to “an implementation,” “some implementations,” “one implementation” or the like are not necessarily mutually exclusive and are intended to indicate that a particular feature, structure, or characteristic described in connection with the implementation may be included in at least one implementation or example. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

What is claimed is:

1. An apparatus, comprising:
a load bank module configured to electrically couple with at least one other load bank module, the load bank module and the at least one other load bank module further configured to electrically couple to a power source to dissipate power received from the power source;
the load bank module comprising a plurality of trays comprising resistive components to dissipate the power received from the power source at a voltage level of the power source; and
a resistive component of the resistive components comprising a coil, the coil extending between a first end of the resistive component and a second end of the resistive component opposite the first end of the resistive component to form three or more turns of the coil.

2. The apparatus of claim 1, comprising:
a plurality of load bank modules comprising the load bank module and the at least one other load bank module, the plurality of load bank modules having a total bottom surface area, the total bottom surface area comprising:
a length of 14.63 meters or less; and
a width 2.5 meters or less;
wherein the plurality of load bank modules are configured to dissipate at least 20 megawatts of power received from the power source.

3. The apparatus of claim 1, wherein the voltage level is up to 33,000 volts alternating current.

4. The apparatus of claim 1, wherein:
the load bank module has dimensions, comprising:
a length of 3 meters or less;
a width 2.5 meters or less; and
a height of 2.9 meters or less;
wherein the load bank module is configured to dissipate at least 4 megawatts of power received from the power source.

5. The apparatus of claim 1, wherein:
the plurality of trays are stacked in columns within an enclosure of the load bank module, the plurality of trays electrically coupled together with bus bars;
a first set of the plurality of trays is coupled with a first phase of the power source;
a second set of the plurality of trays is coupled with a second phase of the power source; and
a third set of the plurality of trays is coupled with a third phase of the power source.

6. The apparatus of claim 1, further comprising:
a first fuse configured to disconnect a first set of the plurality of trays from a first phase of the power source responsive to a level of current of the first phase exceeding a first threshold;
a second fuse configured to disconnect a second set of the plurality of trays from a second phase of the power source responsive to a level of current of the first phase exceeding a second threshold; and
a third fuse configured to disconnect a third set of the plurality of trays from a third phase of the power source responsive to a level of current of the first phase exceeding a third threshold.

7. The apparatus of claim 1, wherein the load bank module comprises a plurality of lateral sides, at least one of the plurality of lateral sides comprising a first rail;
wherein a tray of the plurality of trays comprises at least one second rail to couple with the first rail, the tray configured to install with the load bank module or uninstall from the load bank module via the first rail and the second rail.

8. The apparatus of claim 1, wherein a tray of the plurality of trays comprises at least one lateral wall comprising mica.

9. The apparatus of claim 1, wherein:
a tray of the plurality of trays comprises a lateral wall comprising a plurality of openings; and
the resistive components are configured to be inserted from a first side of the lateral wall, through the plurality of openings, to a second side of the lateral wall.

10. The apparatus of claim 1, wherein a tray of the plurality of trays comprises a lateral wall comprising a plurality of rows of openings from a bottom side of the lateral wall to a top side of the lateral wall, a first row of the plurality of rows of openings offset from a second row of the plurality of rows of openings towards a third side of the lateral wall that extends from the top side to the bottom side;
wherein the resistive components are configured to be inserted from a first side of the lateral wall, through the plurality of rows of openings, to a second side of the lateral wall.

11. The apparatus of claim 1, wherein:
a tray of the plurality of trays comprises a lateral wall comprising a plurality of openings;
the resistive components are installed within the tray, wherein bodies of the resistive components are at least partially disposed on a first side of the lateral wall;
at least a portion of the resistive components extend from the first side of the lateral wall, through the plurality of openings, to expose a plurality of terminals of the resistive components on a second side of the lateral wall; and
a plurality of bus bars configured to couple the resistive components via the plurality of terminals on the second side of the lateral wall.

12. The apparatus of claim 1, wherein the resistive component comprises:
a support member having a cylindrical shape, the support member extending from the first end of the resistive component to the second end of the resistive component;
a plurality of discs coupled with the support member and spaced between the first end of the resistive component and the second end of the resistive component, the plurality of discs comprising openings having circular shapes; and
a wire extending back and forth from a first end of the resistive component to a second end of resistive through the openings in the plurality of discs in a spiral pattern to form a plurality of turns.

13. The apparatus of claim 1, wherein the load bank module comprises a fan apparatus disposed between a bottom of the load bank module and the plurality of trays of the load bank module, the fan apparatus comprising:
at least one air guide vane configured to direct an airflow from a first direction ninety degrees to a second direction; and
a plurality of blowers configured to pull air from outside the load bank module and the air guide vane to direct the airflow away from the bottom to pass through the plurality of trays and cool the resistive components.

14. The apparatus of claim 1, wherein a tray of the plurality of trays comprises a first lateral side and a second lateral side opposite the first lateral side; and the apparatus further comprises a sensor comprising:
a body having a cylindrical shape; and
at least one sensing component disposed at least partially in the body to measure an environmental condition within a column of trays.

15. A method, comprising:
providing a support member having a cylindrical shape;
extending a coil between a first end of the support member and a second end of the support member opposite the first end to form three or more turns of the coil;
disposing the resistive component in a tray of a plurality of trays to dissipate power received from a power source; and
disposing the plurality of trays in a load bank module.

16. The method of claim 15, comprising:
stacking the plurality of trays in columns within an enclosure of the load bank module;
coupling a first set of the plurality of trays with a first phase of the power source;
coupling a second set of the plurality of trays with a second phase of the power source; and
coupling a third set of the plurality of trays with a third phase of the power source.

17. The method of claim 15, comprising:
coupling a first rail with a lateral side of a plurality of lateral sides of the tray of the plurality of trays;
coupling a second rail with a lateral side of a plurality of lateral sides of the load bank module; and
installing or uninstalling, via the first rail and the second rail, the tray with the load bank module.

18. The method of claim 15, comprising:
disposing a plurality of discs on the support member spaced from the first end to the second end; and
disposing a wire in the resistive component by passing the wire back and forth from the first end to the second end through openings in the plurality of discs in a spiral pattern to form a plurality of turns.

19. An apparatus, comprising:
a support member configured to install in, and remove from, a load bank, the support member comprising a first end and a second side opposite the first end; and
a coil extending between the first end of the support member and the second end of the support member to form turns of the coil.

20. The apparatus of claim 19, comprising:
a plurality of discs coupled with the support member and spaced between the first end of the support member and the second end of the support member, the plurality of discs comprising openings having circular shapes; and
a wire extending back and forth from a first side of the support member to a second side of support member through the openings in the plurality of discs in a spiral pattern to form the turns of the coil.
